(19) United States
(12) Patent Application Publication
(10) Pub. No.: US 2026/0101814 A1
(43) Pub. Date: Apr. 9, 2026

(54) Power Semiconductor Device Package

(71) Applicant: Wolfspeed, Inc., Durham, NC (US)

(72) Inventors: Devarajan Balaraman, Apex, NC (US); Afshin Dadvand, Durham, NC (US); Yusheng Lin, Phoenix, AZ (US)

(21) Appl. No.: 18/908,387

(22) Filed: Oct. 7, 2024

(51) Int. Cl. H01L 25/07; H01L 23/00; H01L 23/498; H01L 29/16; H01L 29/78; H01L 29/872

(52) U.S. Cl. CPC H10W 90/00; H10D 8/60; H10D 30/665; H10D 62/8325; H10W 70/658; H10W 72/0198; H10W 72/5445; H10W 72/884; H10W 90/736; H10W 90/753; H10W 90/756

(57) ABSTRACT

Power semiconductor device packages and methods for manufacturing the same are provided. In one example, a power semiconductor device package may include a housing, a submount, and a conjoined semiconductor die structure on the submount. The conjoined semiconductor die structure may include at least two semiconductor die having a common substrate. The conjoined semiconductor die structure may be cut from a semiconductor wafer and may be packaged based on die viability data indicative of an operability of each respective semiconductor die of the at least two semiconductor die.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a power semiconductor device package. The power semiconductor device package includes a housing, a submount, and a conjoined semiconductor die structure on the submount. The conjoined semiconductor die structure includes a first semiconductor die and a second semiconductor die. The first semiconductor die and the second semiconductor die include a common substrate.

Another example aspect of the present disclosure is directed to a method. The method includes cutting a semiconductor wafer into a plurality of conjoined semiconductor die structures. Each conjoined semiconductor die structure includes at least two semiconductor die having a common substrate. The method further includes, for each of the plurality of conjoined semiconductor die structures, obtaining die viability data indicative of an operability of each respective semiconductor die of the at least two semiconductor die and packaging the conjoined semiconductor die structure to form a power semiconductor device package based on the die viability data.

Another example aspect of the present disclosure is directed to a power semiconductor device package. The power semiconductor device package includes a housing, a submount, and a conjoined semiconductor die on the submount. The conjoined semiconductor die includes a first semiconductor die unit, a second semiconductor die unit, and one or more uncut scribe lines on a side of the conjoined semiconductor die. The one or more uncut scribe lines are between the first semiconductor die unit and the second semiconductor die unit.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a top view of an example semiconductor wafer according to example embodiments of the present disclosure;

FIGS. 2A-2C depict cross-sectional views of an example conjoined semiconductor die structure according to example embodiments of the present disclosure;

FIGS. 3A-3B depict top plan views of an example conjoined semiconductor die structure according to example embodiments of the present disclosure;

FIG. 4 depicts an overview of an example method according to example embodiments of the present disclosure;

FIG. 5 depicts an overview of an example method according to example embodiments of the present disclosure;

FIGS. 6A-6C depict top plan views of an example power semiconductor device package according to example embodiments of the present disclosure;

FIGS. 7A-7C depict top plan views of an example power semiconductor device package according to example embodiments of the present disclosure;

FIGS. 8A-8D depict top plan views of an example power semiconductor device package according to example embodiments of the present disclosure;

FIG. 9 depicts a top plan view of an example power semiconductor device package according to example embodiments of the present disclosure;

FIG. 10 depicts a top plan view of an example power semiconductor device package according to example embodiments of the present disclosure;

FIG. 11 depicts a top plan view of an example power semiconductor device package according to example embodiments of the present disclosure;

FIG. 12 depicts a flow chart diagram of an example method according to example embodiments of the present disclosure;

FIG. 13 depicts an example semiconductor package of a semiconductor device according to example embodiments of the present disclosure; and

FIG. 14 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages, such as power semiconductor device packages (e.g., discrete power semiconductor device packages, power modules, etc.), have been developed that include a semiconductor die unit (e.g., semiconductor die). In some examples, such semiconductor die include one or more semiconductor devices, such as a metal-oxide-semiconductor field-effect transistor (MOSFET), a Schottky diode, and/or a high electron mobility transistor (HEMT) device. Power semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Power semiconductor device packages with Schottky diodes and/or HEMT devices may be employed in many of the same high-performance power applications described above with respect to MOSFETs. In some examples, power semiconductor device packages with Schottky diodes may be employed in systems that also include power semiconductor device packages with MOSFETs.

Example aspects of the present disclosure are directed to power semiconductor device packages (e.g., discrete power semiconductor device packages, power modules, etc.) for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide (SiC) and/or a Group-III nitride (e.g., gallium nitride).

In some examples, the one or more semiconductor die may include one or more semiconductor devices, such as transistors, diodes, and/or thyristors. It should be understood that the terms “semiconductor device(s)” and/or “power semiconductor device(s)” may be used interchangeably. For instance, in some examples, the one or more semiconductor die may include a metal-oxide-semiconductor field-effect transistor (MOSFET), such as a silicon carbide-based MOSFET. In such examples, the MOSFET(s) may be located between a first (e.g., source) lead and a second (e.g., drain) lead of a power semiconductor device package to form, for instance, a vertical structure power semiconductor device. Additionally and/or alternatively, in some examples, the one or more semiconductor die may include a Schottky diode, such as a silicon carbide-based Schottky diode. In such examples, the Schottky diode(s) may be located between a first (e.g., cathode) lead and a second (e.g., anode) lead of a power semiconductor device package to form, for instance, a vertical structure power semiconductor device. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices and silicon carbide-based Schottky diode devices for purposes of illustration and discussion. Those having ordinary skill in the art, using the disclosures provided herein, will understand that the power semiconductor device packages of the present disclosure may include other power semiconductor devices without deviating from the scope of the present disclosure, such as, by way of non-limiting example, diodes (e.g., PiN diodes, etc.), insulated gate bipolar transistors, HEMTs, and/or other devices. Furthermore, it should be understood that aspects of the present disclosure are discussed with reference to vertical structure power semiconductor devices for purposes of illustration and discussion. Those having ordinary skill in the art, using the disclosures provided herein, will understand that power semiconductor device packages of the present disclosure may include other forms of power semiconductor devices without deviating from the scope of the present disclosure, such as, by way of non-limiting example, horizontal or lateral power semiconductor devices and/or the like.

Power semiconductor devices may be fabricated by performing fabrication processes on a semiconductor wafer. A semiconductor wafer is a thin, disc-shaped sheet of semiconductor material (e.g., silicon (Si), SiC, GaN, etc.) that may serve as the foundation for manufacturing semiconductor devices, such as integrated circuits (ICs) and/or other electronic components. In some examples, semiconductor wafers may include one or more epitaxial layers formed on a substrate. As used herein, an “epitaxial layer” is a single-crystal semiconductor layer grown on top of a substrate using a process called “epitaxial growth” and/or “epitaxy.” The epitaxial layer may be deposited atom-by-atom and may adopt the crystal structure of the underlying substrate. Furthermore, a “substrate” refers to a solid semiconductor material upon which epitaxial layers are formed. A semiconductor wafer is a type of substrate. A substrate may be a homogenous material, such as silicon carbide and/or sapphire and may provide mechanical support for the formation of epitaxial layers. In some examples, substrates may be provided as a semiconductor wafer on which various other layers and structures are formed. By way of non-limiting example, an example epitaxial layer may have a thickness in a range of, for instance, about 0.2 microns (μm) to about 200 microns (μm), and an example substrate may have a thickness in a range of, for instance, about 0.5 microns (μm) to about 1000 microns (μm) or greater.

The semiconductor wafer may be subjected to wafer-level processing and singulated to form individual semiconductor die for use in a power semiconductor device package, such as a discrete power semiconductor device package and/or a power module. More particularly, the semiconductor wafer may include one or more scribe lines between each of a plurality of semiconductor structures on the semiconductor wafer, such as a plurality of semiconductor devices. The semiconductor wafer may then be cut and/or diced along the one or more scribe lines (e.g., along one or more cut lines) between the plurality of semiconductor devices, such that each individual cut piece becomes a semiconductor die that is later packaged in a power semiconductor device package (e.g., discrete power semiconductor device package, power module, etc.).

As used herein, a “scribe line” refers to a line where the semiconductor wafer may later be cut or diced using, for instance, a wire saw and/or a laser. Hence, as used herein, an “uncut scribe line” refers to a scribe line that has not yet been cut and/or diced, and a “cut line” refers to a scribe line that has been cut and/or diced. The semiconductor wafer may include no metal, such as metal layer structures and the like, within a region defined by the one or more scribe lines. Thus, each of the one or more scribe lines (and, hence, the one or more uncut scribe lines) may include a non-metal region. In some examples, the epitaxial layer of the semiconductor wafer may have a reduced thickness in the regions defined by the one or more scribe lines (e.g., relative to the remaining epitaxial layers). In some examples, there may be no epitaxial semiconductor structure in the regions defined by the scribe lines. In some examples, only the substrate of the semiconductor wafer is in the regions defined by the scribe lines (e.g., non-metal region(s)). In this manner, the semiconductor wafer may be cut and/or diced without destroying and/or damaging the semiconductor devices on the semiconductor wafer, the cutting/dicing instrument, and/or the like.

In some power semiconductor device packages, the one or more semiconductor die may be attached to a submount, such as a lead frame and/or a power substrate (e.g., direct bonded copper (DBC) substrate, active metal brazed (AMB) substrate, etc.), by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s) (e.g., aluminum wire bond(s)) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. More particularly, in some examples, the housing may be and/or may include an encapsulating material (e.g., epoxy mold compound (EMC)) formed around at least a portion of the submount and the one or more semiconductor die. Hence, in some examples, the power semiconductor device package may be a discrete power semiconductor device package. The power semiconductor device package may also include one or more electrical leads extending from the housing. In some examples, the power semiconductor device package may include a plurality of electrical leads, each of which extending from a same side of the housing relative to one another. In other examples, the power semiconductor device package may include a plurality of electrical leads, at least one of which extending from a different side of the housing relative to the other electrical leads. It should be understood that, as used herein, a “plurality of electrical leads” includes at least two, or more, electrical leads extending from the housing.

The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more contacts, interconnections, bonding pads, backside layers, metal layers, or metal coatings of the semiconductor device on the semiconductor die.

Example aspects of the present disclosure are directed to power semiconductor device packages for use in high-power, high-current, etc. applications. In such applications, one important design characteristic is the drain-to-source on-resistance (“R_{DS}(on)”) (hereinafter “on-resistance”), which refers to the resistance between the drain (e.g., drain contact) and the source (e.g., source contact”) of the semiconductor die when the semiconductor device is in “on” state (e.g., during operation). Those having ordinary skill in the art will appreciate that reducing the on-resistance of a power semiconductor device package is an important design consideration due to the resulting increases in the overall performance of the power semiconductor device package.

More particularly, the on-resistance of a power semiconductor device package both directly and indirectly affects a variety of operating characteristics of the corresponding power semiconductor device package, such as conduction losses, power efficiency, thermal efficiency, switching speed, overall performance, and/or the like. For instance, as the associated on-resistance increases, current flowing through a power semiconductor device package (e.g., in the “on” state) experiences greater resistance, thereby leading to increased power dissipation in the form of heat. Put differently, as the associated on-resistance increases, an amount of heat generated by the power semiconductor device package during operation likewise increases, thereby increasing thermal stress on the power semiconductor device package and reducing its overall lifespan and reliability. As such, by reducing the on-resistance of a power semiconductor device package, conduction (e.g., power) losses associated with the power semiconductor device package may be reduced, thereby increasing the overall efficiency (e.g., thermal efficiency, power efficiency, etc.) of the power semiconductor device package. Hence, the on-resistance of a power semiconductor device package plays a defining role in the overall efficiency and performance of the power semiconductor device package—particularly in high-power, high-current applications.

Some semiconductor device packages (e.g., single-die semiconductor device packages) increase the size of the semiconductor die itself to achieve a reduced corresponding on-resistance. However, a rate of defects and/or other characteristics that adversely affect the viability and/or operability of the semiconductor die exponentially increases as a size of each semiconductor device on the semiconductor wafer is increased. Hence, increasing the size of the semiconductor die itself adversely affects (e.g., increases) manufacturing costs due to a resulting decrease in the die yield of the semiconductor wafer from which the semiconductor die is singulated. Alternatively, some semiconductor device packages (e.g., multi-die semiconductor device packages) include multiple semiconductor die electrically coupled in parallel within the semiconductor device package to achieve a reduced corresponding on-resistance. However, as the number of semiconductor die included in the semiconductor device package increases, the likelihood that one of the multiple semiconductor die is inoperable (e.g., non-functional) likewise increases, which may result in further decreases to the die yield.

Those having ordinary skill in the art will appreciate that the “die yield” of a semiconductor wafer is an important efficiency measurement that refers to the percentage of functional and/or operational semiconductor die singulated (e.g., diced, cut, etc.) from the semiconductor wafer during the manufacturing process. Put differently, the “die yield” of a semiconductor wafer is a measure of how many viable (e.g., usable) semiconductor die are produced relative to a total number of semiconductor die singulated from a semiconductor wafer.

Accordingly, example aspects of the present disclosure provide power semiconductor device packages for use in high-power, high-current applications (e.g., discrete power semiconductor device packages, power modules, integrated power systems, etc.) and methods for fabricating the same. More particularly, a power semiconductor device package of the present disclosure may include a housing (e.g., epoxy mold compound (EMC)). The power semiconductor device package may further include a submount. To decrease an on-resistance of the power semiconductor device package, the power semiconductor device package may further include a conjoined semiconductor die structure (e.g., conjoined semiconductor die) on the submount that includes at least two (or more) semiconductor die having a common substrate, such as, by way of non-limiting example, a first semiconductor die (e.g., first semiconductor die unit) and a second semiconductor die (e.g., second semiconductor die unit).

As will be discussed in greater detail below, a “conjoined semiconductor die structure” and/or a “conjoined semiconductor die” refers to a monolithic structure having at least two semiconductor die (e.g., at least two semiconductor die units) that are adjacent on and cut from the same semiconductor wafer during the dicing and/or cutting process. It should be understood that the terms “conjoined semiconductor die structure” and “conjoined semiconductor die” may be used interchangeably. It should be further understood that the terms “semiconductor die” and “semiconductor die unit” may also be used interchangeably.

As described in greater detail below, an internal configuration of the conjoined semiconductor die structures described herein may provide a corresponding power semiconductor device package with a reduced on-resistance and, hence, may improve the overall performance and/or efficiency of the corresponding power semiconductor device package in high-power, high-current applications. For instance, as noted above, a conjoined semiconductor die structure of the present disclosure may include a first semiconductor die and a second semiconductor die. In some examples, the conjoined semiconductor die structure may include one or more electrical connectors that electrically couple the first semiconductor die and the second semiconductor die (e.g., in a parallel arrangement). As such, the on-resistance associated with a power semiconductor device package may be reduced. In contrast to other multi-die solutions (e.g., discussed above), example aspects of the present disclosure also address the die yield-related issues described above by obtaining—and packaging the power semiconductor device package based on—die viability data that is indicative of an operability of each respective semiconductor die.

More particularly, a semiconductor wafer may be cut and/or diced into a plurality of conjoined semiconductor die structures. Each conjoined semiconductor die structure may include at least two semiconductor die that are adjacent to one another on the semiconductor wafer. Each of the at least two semiconductor die in each of the plurality of conjoined semiconductor die structures may include a common substrate. For packaging purposes, the at least two semiconductor die of the conjoined semiconductor die structure may be treated as a single, monolithic structure. That is, although each conjoined semiconductor die structure includes at least two semiconductor die, each conjoined semiconductor die structure is treated and assembled as a single semiconductor die during the manufacturing and assembly process.

More particularly, a conjoined semiconductor die structure fabricated from the semiconductor wafer may include a first side and a second side that is opposite the first side. In the example of a conjoined semiconductor die structure having a first semiconductor die and a second semiconductor die, the conjoined semiconductor die structure may include one or more uncut scribe lines on the first side between the first semiconductor die and the second semiconductor die; the common substrate may be a monolithic structure on the second side. During the manufacturing process, the conjoined semiconductor die structure may be singulated from the semiconductor wafer along the one or more scribe lines (e.g., one or more cut lines) that extend around, but not between, the first semiconductor die and the second semiconductor die. Hence, the conjoined semiconductor die structure may be singulated (e.g., cut, diced) from the semiconductor wafer as a single, monolithic die structure.

To address the die yield-related issues described above, die viability data may be obtained for each respective semiconductor die of the at least two semiconductor die, and the conjoined semiconductor die structure may be packaged to form a power semiconductor device package based on the die viability data. As used herein, “die viability data” is data indicative of an operability of the respective semiconductor die, such as defect data, functionality data, and/or the like. More particularly, during the manufacturing process, the semiconductor wafer (e.g., the plurality of semiconductor devices of the plurality of semiconductor die) may undergo a series of process control and/or reliability tests to identify characteristics in the semiconductor wafer which may, if not identified, result in inoperable semiconductor die and/or inoperable power semiconductor device packages. As one example, semiconductor wafers and epitaxy have inherent defects and/or other characteristics that may cause one or more of the plurality of semiconductor die to be inoperable. Thus, each of the plurality of semiconductor die (e.g., each of the plurality of semiconductor devices) may be tested prior to cutting and/or dicing the semiconductor wafer to obtain die viability data that is indicative of an operability of each respective semiconductor die of the semiconductor wafer.

It should be understood that, as used herein, the term “inactive semiconductor die” and/or “inactive semiconductor die unit” refers to any of the plurality of semiconductor die that is identified as being non-functioning, defective, non-operational, etc., based on the obtained die viability data. In some examples, no current flows through an inactive semiconductor die during operation of the corresponding power semiconductor device package. It should also be understood that, as used herein, the term “active semiconductor die” and/or “active semiconductor die unit” refers to any of the plurality of semiconductor die that is identified as being functioning, non-defective, operational, etc., based on the obtained die viability data. In some examples, current flows through an active semiconductor die during operation of the corresponding power semiconductor device package.

As a non-limiting illustrative example, it may be determined that each of the at least two semiconductor die are active (e.g., functioning, non-defective, operational, etc.) semiconductor die based on the die viability data. In such examples, the conjoined semiconductor die structure may be packaged to form the power semiconductor device package such that each of the at least two active semiconductor die are electrically coupled in the power semiconductor device package. In some examples, the at least two active semiconductor die may be electrically coupled in parallel via one or more electrical connectors, such as wire bonds, ribbon bonds, and/or the like.

As another non-limiting illustrative example, it may be determined that at least one semiconductor die is an inactive (e.g., non-functioning, defective, non-operational, etc.) semiconductor die and at least one semiconductor die is an active semiconductor die based on the die viability data. In such examples, the conjoined semiconductor die structure may be packaged to form the power semiconductor device package such that no current flows through the inactive semiconductor die during operation. In this way, although one semiconductor die is an inactive semiconductor die, the conjoined semiconductor die structure may be packaged as a single-die power semiconductor device package, thereby increasing the die yield of the semiconductor wafer from which the conjoined semiconductor die structure is singulated.

Aspects of the present disclosure provide a number of technical effects and benefits. For instance, power semiconductor device packages of the present disclosure include a conjoined semiconductor die structure having at least two semiconductor die that share a common substrate. In this way, an on-resistance associated with the power semiconductor device package may be reduced, which improves the overall performance and efficiency of the power semiconductor device package in high-power, high-current applications. Moreover, example aspects of the present disclosure provide reduced manufacturing and assembly costs by virtue of the conjoined semiconductor die structure being treated as a single, monolithic structure. That is, by singulating at least two adjacent semiconductor die from the semiconductor wafer, power semiconductor device packages of the present disclosure require less singulations (e.g., relative to other power semiconductor device packages where each semiconductor die is individually singulated), thereby providing manufacturing- and assembly-related cost savings. Moreover, by packaging each power semiconductor device package based on die viability data, example aspects of the present disclosure increase a die yield of semiconductor wafers. Additionally, in examples where at least one semiconductor die is identified as being an inactive semiconductor die, the inactive semiconductor die may provide an additional heat dissipation path for the power semiconductor device package, thereby increasing a thermal efficiency of the power semiconductor device package.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

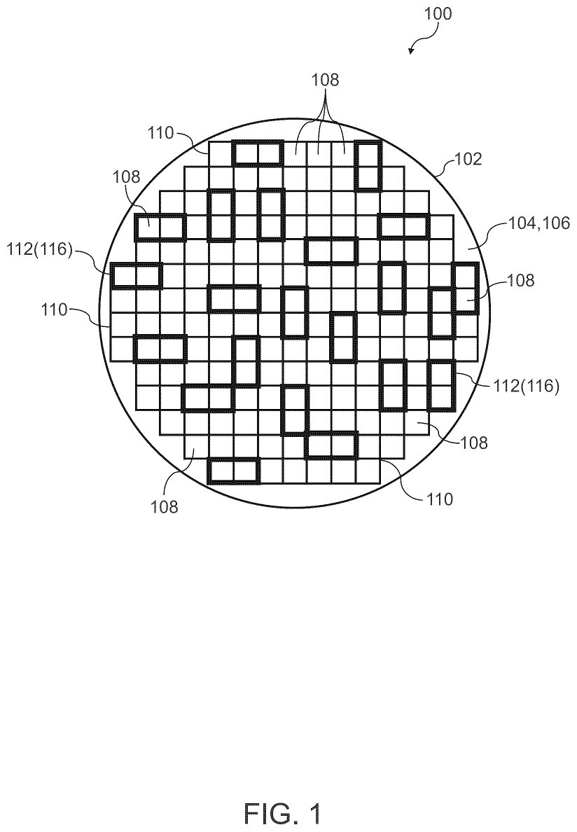

FIG. 1 depicts a top view of an example semiconductor wafer 100 according to example embodiments of the present disclosure. As noted above, the semiconductor wafer 100 may serve as the foundation for manufacturing a plurality of semiconductor devices, such as integrated circuits (ICs) and/or other electronic components. It should be understood that FIG. 1 is intended to represent structures for purposes of identification and description and is not intended to represent the structures to physical scale.

The semiconductor wafer 100 may be a thin, disc-shaped sheet of semiconductor material, such as silicon (Si), silicon carbide (SiC), gallium nitride (GaN), and the like. The semiconductor wafer 100 may include a semiconductor structure with other material layers, such as insulating layers and/or metal layers, provided thereon. More particularly, the semiconductor wafer 100 may include a substrate 102. The substrate 102 may include a semiconductor material, such as a wide bandgap semiconductor material. By way of non-limiting example, the substrate 102 may be a silicon (Si) substrate, a silicon carbide (SiC) substrate, a Group III-nitride (e.g., gallium nitride (GaN)) substrate, a sapphire substrate, and/or other suitable substrates. In some examples, the semiconductor substrate 102 may be a SiC substrate that may include, for example, the 4H polytype of SiC or may be the 3C, 6H, and/or 15R polytypes of SiC.

Other semiconductor layers (e.g., polysilicon gate layers), insulating layers, and/or metal layers may be provided on the substrate 102 to form a plurality of semiconductor devices. For instance, in some examples, the semiconductor wafer 100 may include one or more epitaxial layers 104, which may be a single-crystal semiconductor layer grown on a top side of the substrate 102. In some examples, the semiconductor wafer 100 may include one or more passivation layers 106 having any suitable passivation material, such as one or more silicon nitride layers, one or more polymer layers, and/or the like. In this manner, the substrate 102 may be a semiconductor structure. As used herein, a “semiconductor structure” refers to a structure having one or more semiconductor layers, such as semiconductor substrates and/or semiconductor epitaxial layers.

As noted above, a plurality of semiconductor devices may be formed on the substrate 102. More particularly, as shown, the semiconductor wafer 100 may include a plurality of semiconductor die units 108 (hereinafter “semiconductor die 108”). Each semiconductor die 108 may include a wide bandgap semiconductor material, such as, by way of non-limiting example, silicon carbide (SiC), a Group III-nitride (e.g., gallium nitride (GaN)), and/or the like. Each semiconductor die 108 may further include one or more semiconductor devices, such as, by way of non-limiting example, a metal-oxide-semiconductor field-effect transistor (MOSFET), a Schottky diode, and/or the like. Furthermore, metal layer structures (e.g., metallization structures) may be provided on one or more sides of each semiconductor die 108 to form contacts for each semiconductor die 108 (e.g., for each corresponding semiconductor device). Although described herein as being vertical semiconductor die, it should be understood that the plurality of semiconductor die 108 may also be lateral semiconductor die without deviating from the scope of the present disclosure.

The plurality of semiconductor die 108 may be provided in rows and columns on the substrate 102 and may be spaced apart from each other such that the semiconductor wafer 100 may later be subjected to a singulation process (e.g., cutting process, dicing process, etc.) to separate the individual semiconductor die 108 for packaging and testing. For instance, the semiconductor wafer 100 may be subjected to wafer-level processing and diced to form the plurality of semiconductor die 108, each of which having one or more semiconductor devices. The semiconductor wafer 100 may be cut and/or diced (e.g., using a wire saw and/or a laser) along a portion of the semiconductor wafer 100 that runs between each of the semiconductor devices such that each individual cut piece becomes a semiconductor die 108 that is later packaged in a semiconductor device package (e.g., discrete semiconductor device package, power module, etc.).

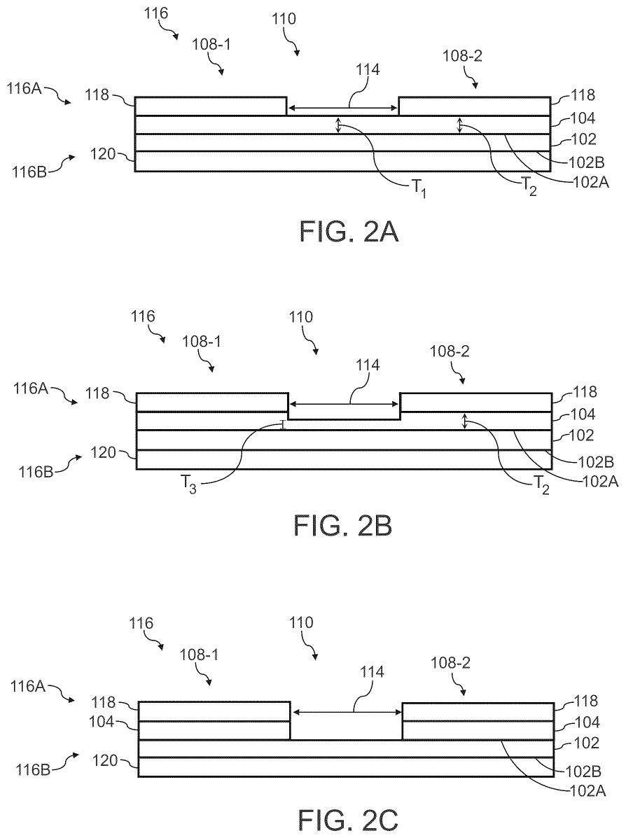

More particularly, the semiconductor wafer 100 may include one or more scribe lines 110 between each of semiconductor devices on the substrate 102. As noted above, the one or more scribe lines 110 define where the semiconductor wafer 100 may later be cut and/or diced using, for instance, a wire saw, a laser, and/or the like. The semiconductor wafer 100 may further include one or more cut lines 112, which correspond to a scribe line 110 that has been cut and/or diced. The semiconductor wafer 100 may include no metal, such as metal layer structures and/or the like, within a region defined by the one or more scribe lines 110. Hence, the one or more scribe lines 110 and/or the one or more cut lines 112 may include, and may likewise define, a non-metal region 114 (FIGS. 2A-2C) of the semiconductor wafer 100.

The semiconductor wafer 100 may be singulated (e.g., cut, diced, etc.) into a plurality of conjoined semiconductor die structures 116 along the one or more cut lines 112, and each conjoined semiconductor die structure 116 may be encapsulated (e.g., packaged) to form a power semiconductor device package. In this way, the one or more cut lines 112 may group the plurality of semiconductor die 108 into a plurality of conjoined semiconductor die structures 116. As will be discussed in greater detail below, each conjoined semiconductor die structure 116 may include at least two semiconductor die 108 having a common substrate (e.g., substrate 102). Each conjoined semiconductor die structure 116 may include at least one uncut scribe line 110 between adjacent semiconductor die 108 of the at least two semiconductor die 108.

Referring now to FIGS. 2A-2C, cross-sectional views of an example conjoined semiconductor die structure 116 singulated (e.g., cut, diced, etc.) from the semiconductor wafer 100 are depicted according to example embodiments of the present disclosure. It should be understood that FIGS. 2A-2C are intended to represent structures for purposes of identification and description and are not intended to represent the structures to physical scale.

As shown in FIGS. 2A-2C, the substrate 102 of the semiconductor wafer 100 may have a first (e.g., top) side 102A and a second (e.g., bottom) side 102B that is opposite the first side 102A. The conjoined semiconductor die structure 116 may also include a first side 116A and a second side 116B that is opposite the first side 116A. As shown in FIGS. 2A-2C, the first side 116A of the conjoined semiconductor die structure 116 may correspond to the first side 102A of the substrate 102. Likewise, the second side 116B of the conjoined semiconductor die structure 116 may correspond to the second side 102B of the substrate 102.

As noted above, each conjoined semiconductor die structure 116 may include at least two semiconductor die 108. In the example depicted in FIGS. 2A-2C, each conjoined semiconductor die structure 116 includes a first semiconductor die 108-1 and a second semiconductor die 108-2 for purposes of illustration and discussion. Those having ordinary skill in the art, using the disclosures provided herein, will understand that example conjoined semiconductor die structures 116 of the present disclosure may include any suitable number of semiconductor die 108 without deviating from the scope of the present disclosure.

The conjoined semiconductor die structure 116 may include one or more metallization structures, such as one or more metallization structures operable to facilitate an electrical connection between the conjoined semiconductor die structure 116 and one or more external devices (e.g., via one or more electrical connectors). The one or more metallization structures may be any suitable metallization structure, such as a bonding pad, ohmic contact, and/or the like. For instance, as shown in FIGS. 2A-2C, each semiconductor die 108 of the conjoined semiconductor die structure 116 may include one or more metallization structures 118 on the first side 116A of the conjoined semiconductor die structure 116. The conjoined semiconductor die structure 116 may further include a backside metallization structure 120 on the second side 116B of the conjoined semiconductor die structure 116. The backside metallization structure 120 may, in some examples, be a monolithic structure that is continuous across the second side 116B of the conjoined semiconductor die structure 116. That is, while each semiconductor die 108 of the conjoined semiconductor die structure 116 (e.g., semiconductor die 108-1, semiconductor die 108-2) may have separate metallization structures 118 on the first side 116A, each semiconductor die 108 (e.g., semiconductor die 108-1, semiconductor die 108-2) may share a common backside metallization structure 120 and a common substrate (e.g., substrate 102). In some examples, the backside metallization structure 120 may be secured to a submount (e.g., lead frame) using, for instance, a die-attach material to provide a thermal and/or electrical connection for the conjoined semiconductor die structure 116.

Each semiconductor die 108 may include one or more semiconductor devices. As one non-limiting illustrative example, each of the first semiconductor die 108-1 and the second semiconductor die 108-2 may include a metal-oxide-semiconductor field-effect transistor (MOSFET). In such examples, as will be discussed in greater detail below, the metallization structures 118 (e.g., of both the first semiconductor die 108-1 and the second semiconductor die 108-2) on the first side 116A of the conjoined semiconductor die structure 116 may be a source contact, a gate contact, a sensor contact, a source-kelvin contact, and/or the like. Furthermore, the backside metallization structure 120 on the second side 116B of the conjoined semiconductor die structure 116 may be a drain contact (e.g., on a monolithic substrate) for both the first semiconductor die 108-1 and the second semiconductor die 108-2.

As another non-limiting illustrative example, each of the first semiconductor die 108-1 and the second semiconductor die 108-2 may include a Schottky diode. In such examples, as will be discussed in greater detail below, the metallization structures 118 (e.g., of both the first semiconductor die 108-1 and the second semiconductor die 108-2) on the first side 116A of the conjoined semiconductor die structure 116 may be an anode contact. Furthermore, the backside metallization structure 120 on the second side 116B of the conjoined semiconductor die structure 116 may be a cathode contact (e.g., on a monolithic substrate) for both the first semiconductor die 108-1 and the second semiconductor die 108-2.

The conjoined semiconductor die structure 116 may further include one or more uncut scribe lines 110 on the first side 116A of the conjoined semiconductor die structure 116. The one or more uncut scribe lines 110 may be between the first semiconductor die 108-1 and the second semiconductor die 108-2. More particularly, the one or more uncut scribe lines 110 may be between adjacent metallization structures 118 on the first side 116A of the conjoined semiconductor die structure 116, such as between the metallization structure 118 of the first semiconductor die 108-1 and the metallization structure 118 of the second semiconductor die 108-2. The conjoined semiconductor die structure 116 (and, hence, the semiconductor wafer 100) includes no metal (e.g., metallization structures 118) in a region defined by the one or more uncut scribe lines 110. In this way, the one or more uncut scribe lines 110 may define the non-metal region 114 of the conjoined semiconductor die structure 116.

As shown in FIGS. 2A-2C, the epitaxial layer 104 may be formed on a side of the substrate 102, such as the first side 102A. In some examples (e.g., FIG. 2A), the epitaxial layer 104 may have a thickness T₁ in the non-metal region 114 that is substantially similar to a thickness T₂ outside of the non-metal region 114. Additionally and/or alternatively, in some examples (e.g., FIG. 2B), the epitaxial layer 104 may have a reduced thickness T₃ in the non-metal region 114 relative to the thickness T₂ outside of the non-metal region 114. Additionally and/or alternatively, in some examples (e.g., FIG. 2C), the epitaxial layer 104 may be etched or otherwise removed from the non-metal region 114 such that no epitaxial layer structure remains (e.g., leaving only the substrate 102) in the non-metal region 114.

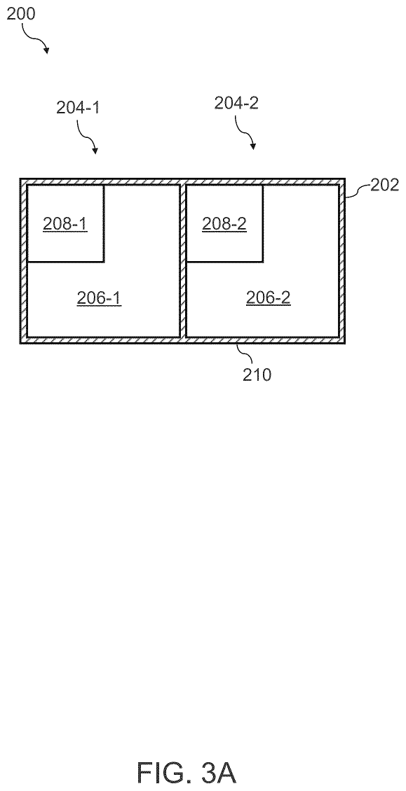

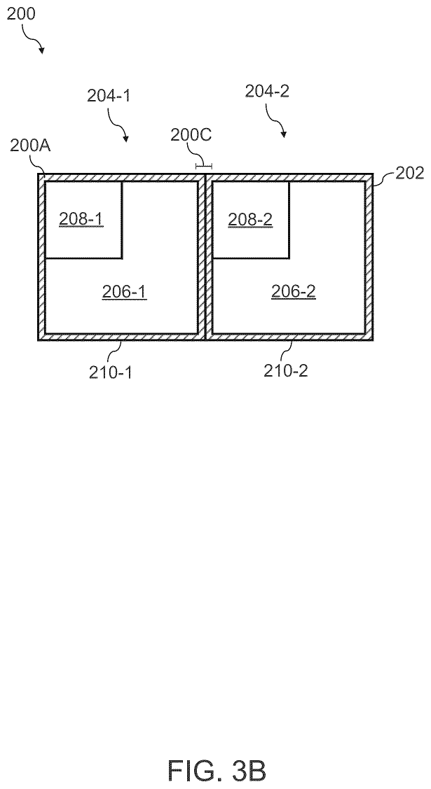

Referring now to FIGS. 3A-3B, top plan views of an example conjoined semiconductor die structure 200 are depicted according to example embodiments of the present disclosure. It should be understood that FIGS. 3A-3B are intended to represent structures for purposes of identification and description and are not intended to represent the structures to physical scale.

The conjoined semiconductor die structure 200 may be similar to any of the conjoined semiconductor die structures described herein, such as the conjoined semiconductor die structure 116 described above with reference to FIGS. 1-2C. For instance, the conjoined semiconductor die structure 200 may be singulated (e.g., cut, diced, etc.) from a semiconductor wafer, such as the semiconductor wafer 100 described above (e.g., FIG. 1). The conjoined semiconductor die structure 200 may include at least two semiconductor die 204, such as the first semiconductor die 204-1 and a second semiconductor die 204-2. The semiconductor die 204 may be similar to any of the semiconductor die described herein, such as the semiconductor die 108 described above (e.g., FIGS. 1-2C). As shown, the first semiconductor die 204-1 and the second semiconductor die 204-2 may include a common substrate 202, which may be similar to the substrate 102 described above (e.g., FIGS. 1-2C).

In the examples depicted in FIGS. 3A-3B, the first semiconductor die 204-1 and the second semiconductor die 204-2 include metal-oxide-semiconductor field-effect transistor (MOSFET) devices. More particularly, as shown, the first semiconductor die 204-1 may include a source contact 206-1 and a gate contact 208-1 on a first side 200A of the conjoined semiconductor die structure 200. The source contact 206-1 and the gate contact 208-1 of the first semiconductor die 204-1 may be similar to any of the metallization structures described herein, such as the metallization structures 118 described above (e.g., FIGS. 2A-2C). The first semiconductor die 204-1 may further include a drain contact (not shown) on a second side (not shown) of the conjoined semiconductor die structure 200 that is opposite the first side 200A. The drain contact (not shown) of the first semiconductor die 204-1 may be similar to any of the backside metallization structures described herein, such as the backside metallization structure 120 described above (e.g., FIGS. 2A-2C). For instance, the drain contact (not shown) of the first semiconductor die 204-1 may be coupled to the common substrate 202. In some examples, the drain contact (now shown) may be directly on the common substrate 202.

Similarly, referring still to FIGS. 3A-3B, the second semiconductor die 204-2 may include a source contact 206-2 and a gate contact 208-2 on the first side 200A of the conjoined semiconductor die structure 200. The source contact 206-2 and the gate contact 208-2 of the second semiconductor die 204-2 may be similar to any of the metallization structures described herein, such as the metallization structures 118 described above (e.g., FIGS. 2A-2C). The second semiconductor die 204-2 may further include a drain contact (not shown) on the second side (not shown) of the conjoined semiconductor die structure 200 that is opposite the first side 200A. In some examples, the drain contact (not shown) of the first semiconductor die 204-1 and the second semiconductor die 204-2 may be on a monolithic substrate. For instance, the drain contact (not shown) of the second semiconductor die 204-2 may be similar to any of the backside metallization structures described herein, such as the backside metallization structure 120 described above (e.g., FIGS. 2A-2C). For instance, the drain contact (not shown) of the second semiconductor die 204-2 may be coupled to the common substrate 202. In some examples, the drain contact (now shown) may be directly on the common substrate 202.

The conjoined semiconductor die structure 200 may further include one or more edge termination regions 210. The edge termination region 210 may be operable to reduce electric field crowding that may occur around a periphery of the conjoined semiconductor die structure 200 and/or in a central portion 200C of the conjoined semiconductor die structure 200. That is, the edge termination region 210 may spread out the electric fields along a periphery of the conjoined semiconductor die structure 200 and/or between the first semiconductor die 204-1 and the second semiconductor die 204-2, which may reduce electric field crowding. The edge termination region 210 may serve to increase a reverse blocking voltage of the conjoined semiconductor die structure 200 at which a phenomenon known as “avalanche breakdown” occurs where an increasing electric field results in runaway generation of charge carriers within the conjoined semiconductor die structure 200, resulting in a sharp increase in current that may damage or even destroy the conjoined semiconductor die structure 200.

It should be understood that, as used here, the “central portion” of the conjoined semiconductor die structure 200 refers to the portion of the conjoined semiconductor die structure 200 that is between the first semiconductor die 204-1 and the second semiconductor die 204-2.

Referring now to FIG. 3A, in some examples, the conjoined semiconductor die structure 200 may include an edge termination region 210 extending around at least a portion of the first semiconductor die 204-1 and the second semiconductor die 204-2. As shown, at least a portion of the edge termination region 210 may extend between the first semiconductor die 204-1 and the second semiconductor die 204-2 in the central portion 200C of the conjoined semiconductor die structure 200.

Referring now to FIG. 3B, in some examples, the conjoined semiconductor die structure 200 may include a first edge termination region 210-1 extending around a periphery of the first semiconductor die 204-1. The conjoined semiconductor die structure 200 may further include a second edge termination region 210-2 extending around a periphery of the second semiconductor die 204-2. As shown, at least a portion of the first edge termination region 210-1 may be laterally adjacent to at least a portion of the second edge termination region 210-2 in the central portion 200C of the conjoined semiconductor die structure 200.

It should be understood that the conjoined semiconductor die structure 200 is depicted in FIGS. 3A-3B as including at least two semiconductor die 204 having MOSFETs for purposes of illustration and discussion. Those having ordinary skill in the art, using the disclosures provided herein, will understand that the semiconductor die 204 depicted in FIGS. 3A-3B may include any suitable semiconductor device without deviating from the scope of the present disclosure, such as Schottky diode(s), high electron mobility transistor(s) (HEMT(s)), bipolar junction transistor(s) (BJT(s)), insulated-gate bipolar transistor(s) (IGBT(s)), gate turn-off thyristor(s) (GTO(s)), junction field-effect transistor(s) (JFET(s)), and/or the like.

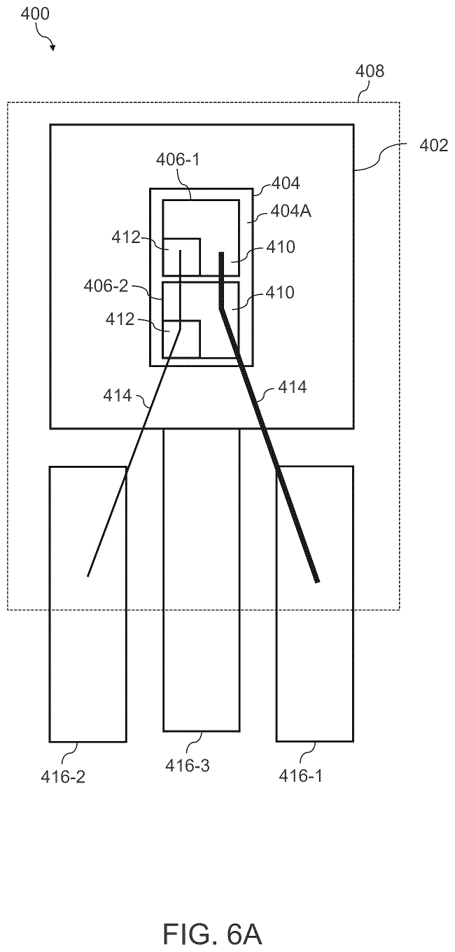

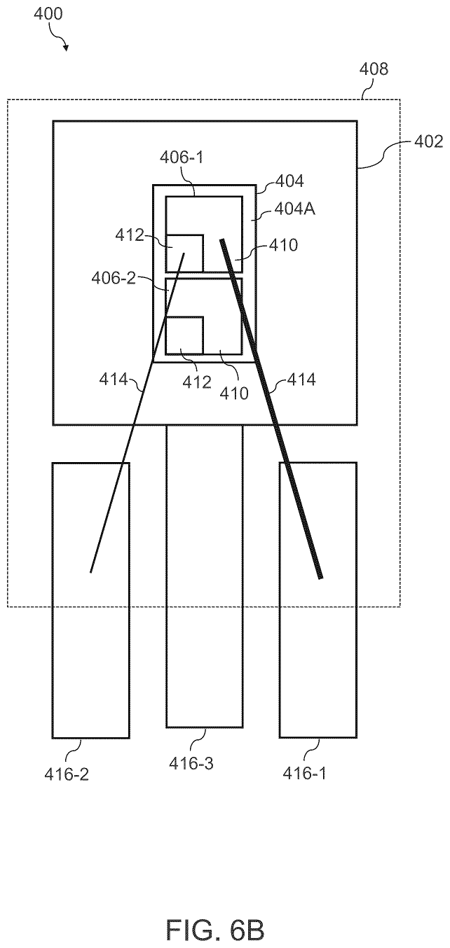

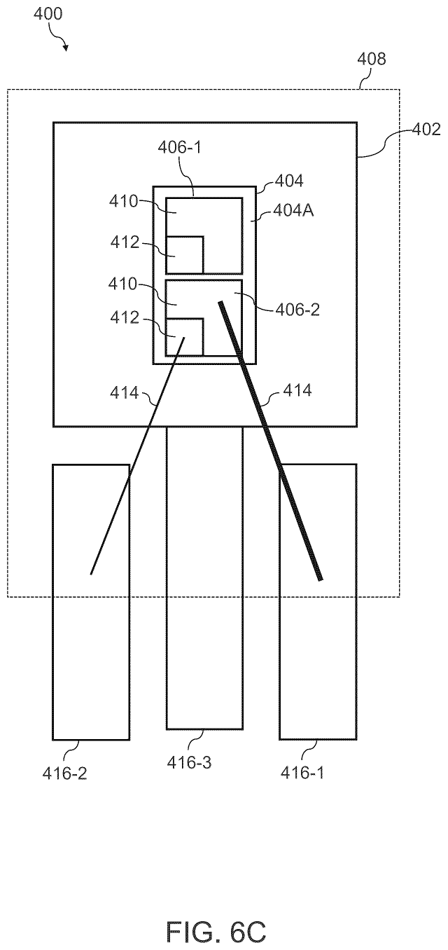

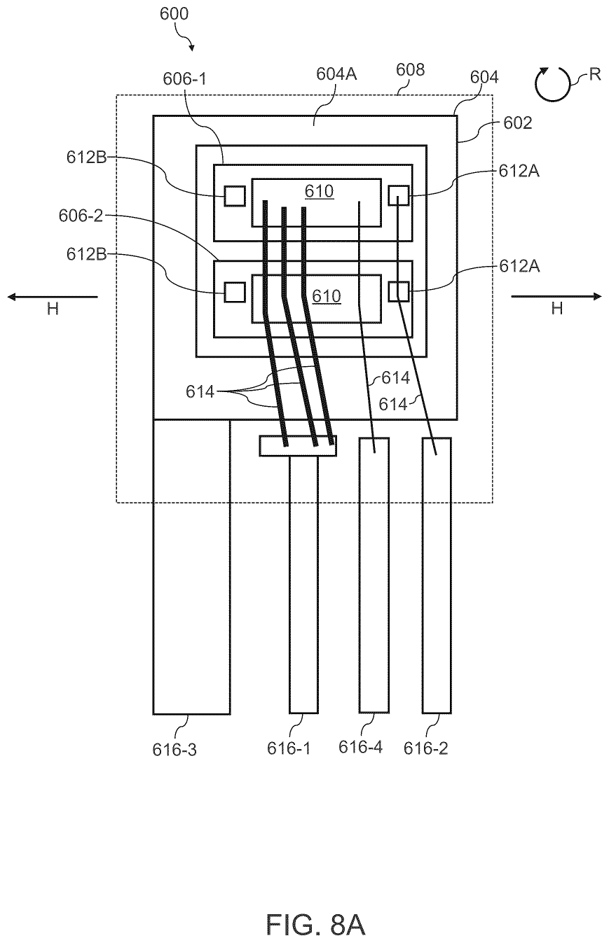

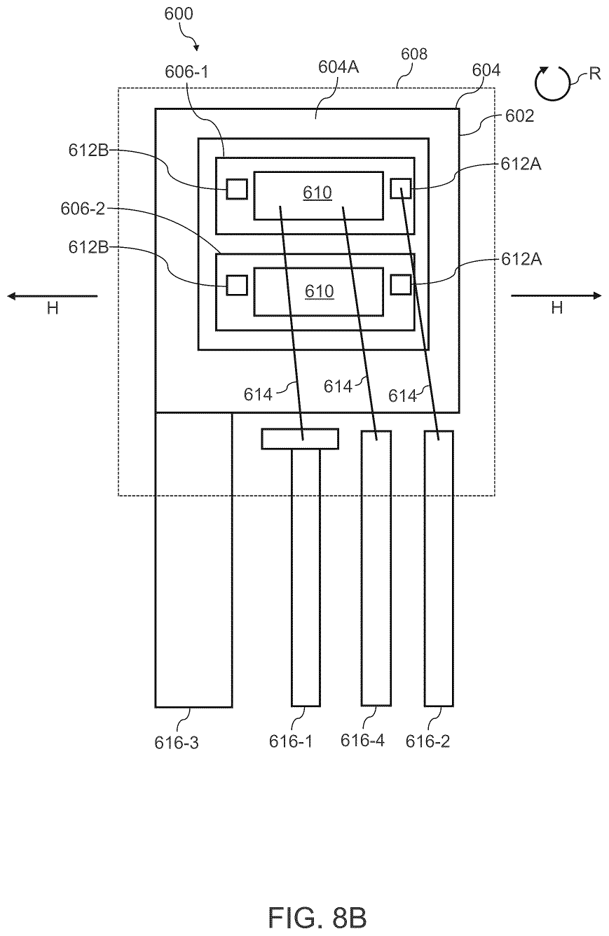

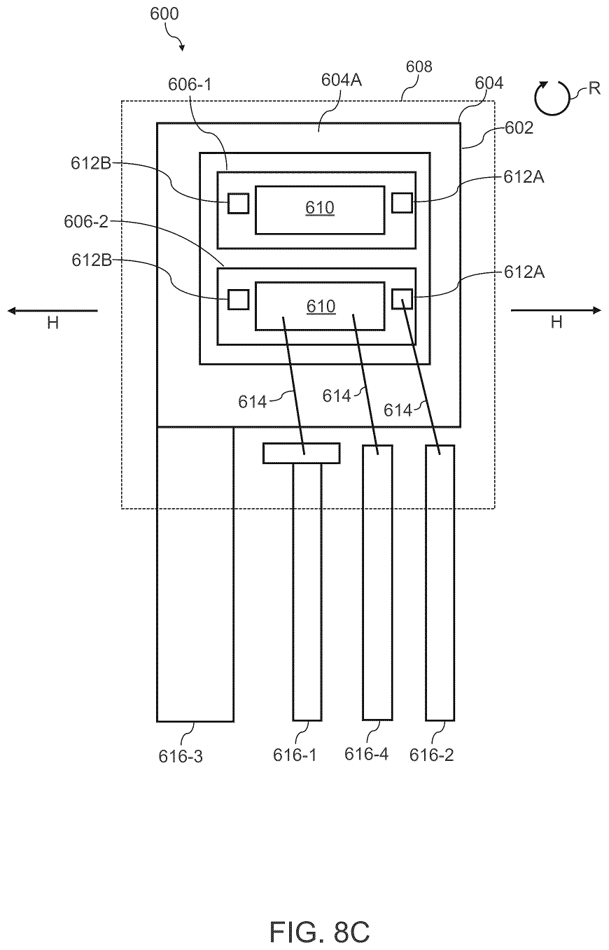

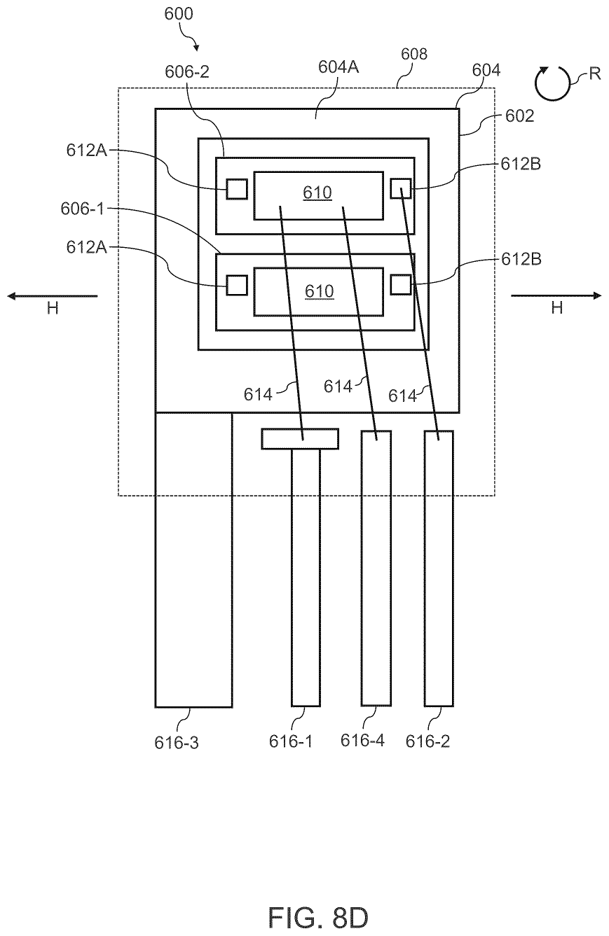

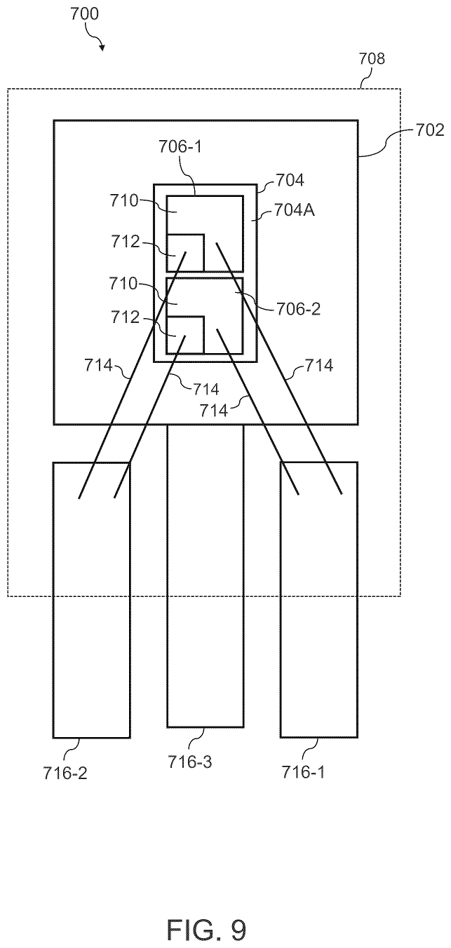

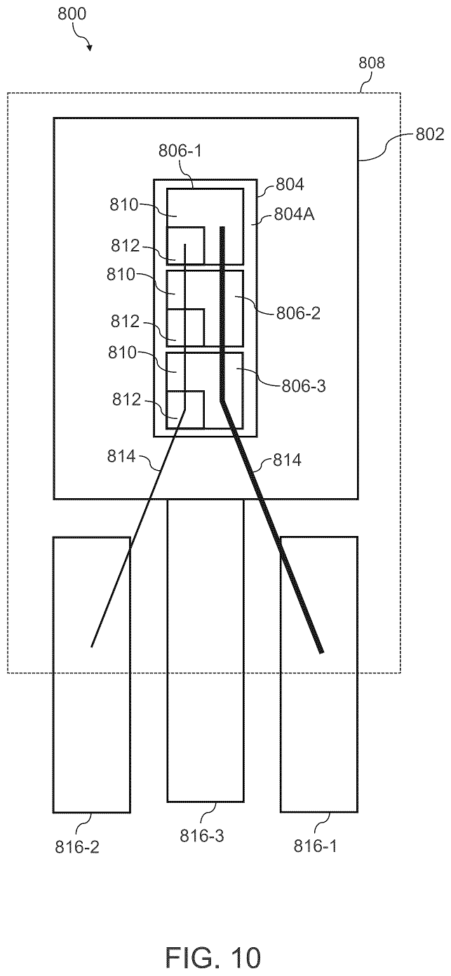

Variations and modifications may be made to the example conjoined semiconductor die structures (e.g., conjoined semiconductor die structure 116 (FIGS. 1-2C), conjoined semiconductor die structure 200 (FIGS. 3A-3B)) without deviating from the scope of the present disclosure. For instance, an example conjoined semiconductor die structure may have a different arrangement and/or configuration of metallization structures and/or contacts on the first side of the conjoined semiconductor die structure. As one example, an example conjoined semiconductor die structure may include a gate contact that includes two gate pads (e.g., FIGS. 8A-8D). Additionally and/or alternatively, an example conjoined semiconductor die structure may include at least two semiconductor die having any suitable power semiconductor device. As one example, an example conjoined semiconductor die structure may include at least two semiconductor die having Schottky diodes (e.g., FIGS. 6A-6C). Additionally and/or alternatively, an example conjoined semiconductor die structure may include more than two semiconductor die, such as at least three semiconductor die (e.g., FIG. 9), four or more semiconductor die (e.g., FIG. 10), and/or the like.

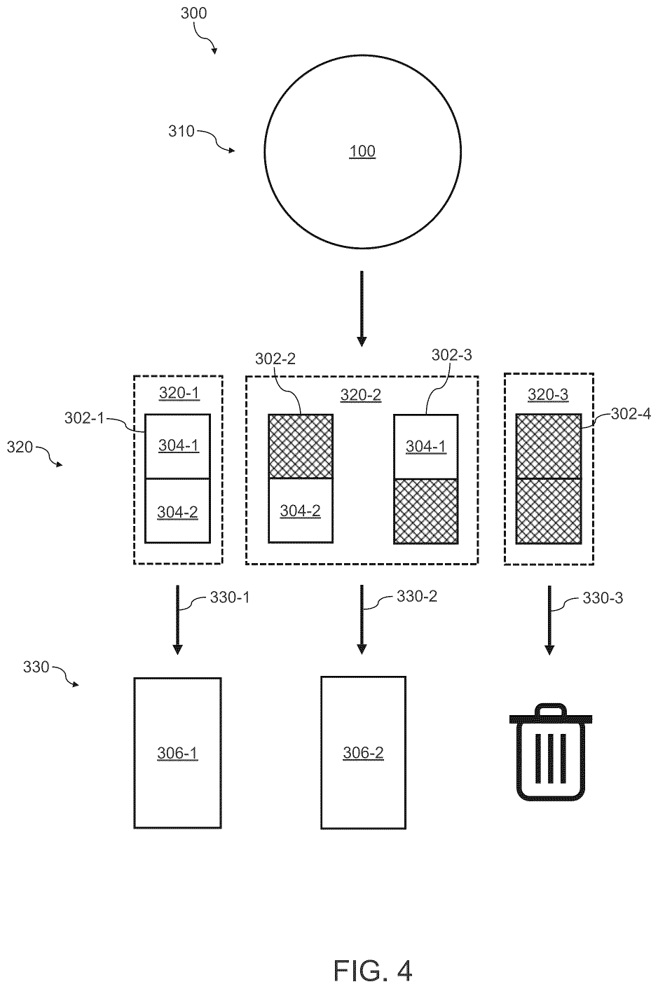

FIG. 4 depicts an illustrative overview of an example method 300 according to example embodiments of the present disclosure. As discussed in greater detail below, the method 300 depicted in FIG. 4 may serve to increase a die yield associated with the semiconductor wafer 100. FIG. 4 is intended to represent structures for identification and description and is not intended to represent the structures to physical scale. The method 300 includes operations illustrated in a particular order for purposes of illustration and discussion. Those having ordinary skill in the art, using the disclosures provided herein, will understand that the various steps or operations of any of the methods provided in this disclosure may be adapted, rearranged, omitted, include steps not illustrated, and/or modified in various ways without deviating from the scope of the present disclosure.

At 310, the method 300 may include cutting the semiconductor wafer 100 into a plurality of conjoined semiconductor die structures 302 (e.g., conjoined semiconductor die structures 302-1-302-4). It should be understood that only four conjoined semiconductor die structures 302 are depicted in FIG. 4 for purposes of illustration and discussion. Those having ordinary skill in the art, using the disclosures provided herein, will understand that any number of conjoined semiconductor die structures may be cut from the semiconductor wafer 100 without deviating from the scope of the present disclosure.

Each conjoined semiconductor die structure 302 may be similar to any of the conjoined semiconductor die structures described herein, such as the conjoined semiconductor die structure 116 (FIGS. 1-2C), the conjoined semiconductor die structure 200 (FIGS. 3A-3B), and/or the like. For instance, as shown, each conjoined semiconductor die structure 302 may include at least two semiconductor die 304. More particularly, each conjoined semiconductor die structure 302 may include a first semiconductor die 304-1 and a second semiconductor die 304-2. Each semiconductor die 304 may be similar to any of the semiconductor die described herein, such as the semiconductor die 108 (FIGS. 1-2C), the semiconductor die 204 (FIGS. 3A-3B), and/or the like. In some examples, each semiconductor die 304 may include a metal-oxide-semiconductor field-effect transistor (MOSFET). Additionally and/or alternatively, in some examples, each semiconductor die 304 may include a Schottky diode. However, those having ordinary skill in the art, using the disclosures provided herein, will understand that the semiconductor die 304 may include any suitable semiconductor device without deviating from the scope of the present disclosure.

At 320, the method 300 may include obtaining die viability data associated with each of the plurality of conjoined semiconductor die structures 302 singulated from the semiconductor wafer 100. As noted above, die viability data refers to data that is indicative of an operability of each respective semiconductor die 304 of each of the plurality of conjoined semiconductor die structures 302. At 330, the method 300 may include packaging each of the plurality of conjoined semiconductor die structures 302 to form a power semiconductor device package 306 based on the die viability data obtained at 320.

By way of non-limiting illustrative example, at 320-1, die viability data may be obtained for each of the first semiconductor die 304-1 and the second semiconductor die 304-2 of the conjoined semiconductor die structure 302-1. Based on the die viability data obtained at 320-1, the first semiconductor die 304-1 and the second semiconductor die 304-2 may be determined to be active semiconductor die (e.g., functioning, non-defective, operational, etc.). As such, at 330-1, the conjoined semiconductor die structure 302-1 may be packaged to form a power semiconductor device package 306-1 such that each of the first semiconductor die 304-1 and the second semiconductor die 304-2 are electrically coupled in the power semiconductor device package 306-1.

By way of another non-limiting illustrative example, at 320-2, die viability may be obtained may be obtained for each of the first semiconductor die 304-1 and the second semiconductor die 304-2 of each of the conjoined semiconductor die structures 302-2-302-3. Based on the die viability data obtained at 320-2, at least one of the semiconductor die 304 may be determined to be an inactive semiconductor die (e.g., non-functioning, defective, non-operational, etc.) and at least one semiconductor die 304 may be determined to be an active semiconductor die (e.g., functioning, non-defective, operational, etc.). For instance, in the conjoined semiconductor die structure 302-2, the first semiconductor die 304-1 may be an inactive semiconductor die, and the second semiconductor die 304-2 may be an active semiconductor die. In the conjoined semiconductor die structure 302-3, the first semiconductor die 304-1 may be an active semiconductor die, and the second semiconductor die 304-2 may be an inactive semiconductor die. As such, at 330-2, each conjoined semiconductor die structure 302-2-302-3 may be packaged to form a power semiconductor device package 306-2 such that no current flows through the inactive semiconductor die during operation. For instance, the conjoined semiconductor die structure 302-2 may be packaged such that no current flows through the first semiconductor die 304-1 during operation, and the conjoined semiconductor die structure 302-3 may be packaged such that no current flows through the second semiconductor die 304-2 during operation.

By way of another non-limiting illustrative example, at 320-3, die viability data may be obtained for each of the first semiconductor die 304-1 and the second semiconductor die 304-2 of the conjoined semiconductor die structure 302-4. Based on the die viability data obtained at 320-3, the first semiconductor die 304-1 and the second semiconductor die 304-2 may be determined to be inactive semiconductor die (e.g., non-functioning, defective, non-operational, etc.). As such, at 330-3, the conjoined semiconductor die structure 302-4 may be discarded in response to determining (at 320-3) that each semiconductor die 304 of the conjoined semiconductor die structure 302-4 are inactive semiconductor die.

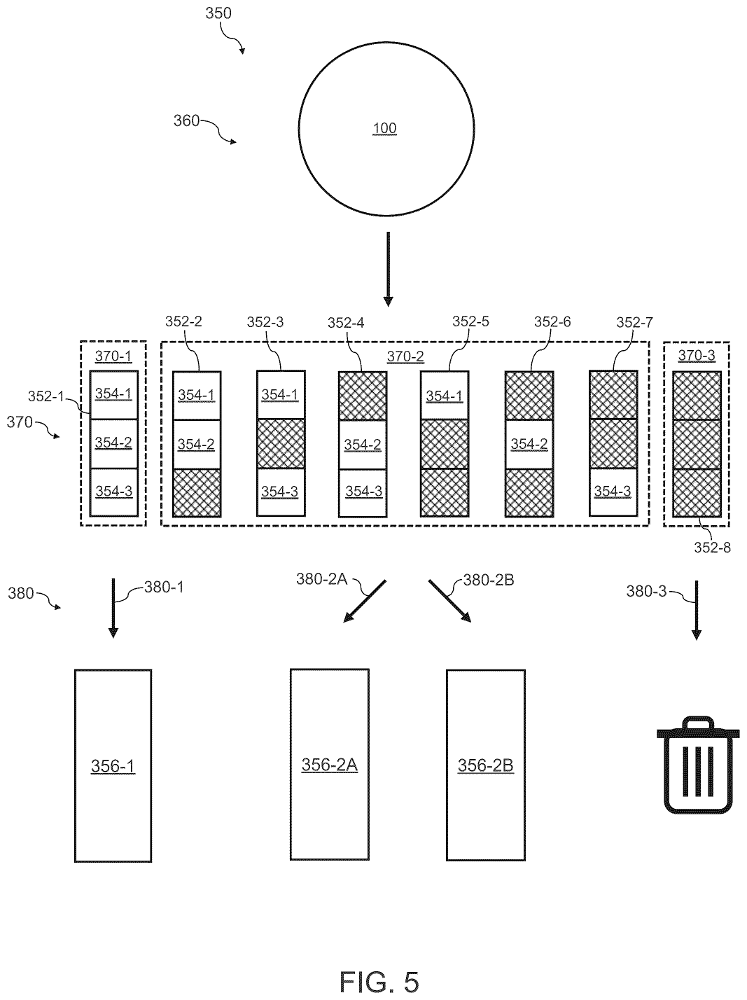

FIG. 5 depicts an illustrative overview of an example method 350 according to example embodiments of the present disclosure. The method 350 may be similar to the method 300 described above with reference to FIG. 4. For instance, the method 350 depicted in FIG. 5 may serve to increase a die yield associated with the semiconductor wafer 100. FIG. 5 is intended to represent structures for identification and description and is not intended to represent the structures to physical scale. The method 350 includes operations illustrated in a particular order for purposes of illustration and discussion. Those having ordinary skill in the art, using the disclosures provided herein, will understand that the various steps or operations of any of the methods provided in this disclosure may be adapted, rearranged, omitted, include steps not illustrated, and/or modified in various ways without deviating from the scope of the present disclosure.

As noted above, the method 350 may be similar to the method 300 (FIG. 4). For instance, at 360, the method 350 may include cutting the semiconductor wafer 100 into a plurality of conjoined semiconductor die structures 352 (e.g., conjoined semiconductor die structures 352-1-352-8). It should be understood that only eight conjoined semiconductor die structures 352 are depicted in FIG. 5 for purposes of illustration and discussion. Those having ordinary skill in the art, using the disclosures provided herein, will understand that any number of conjoined semiconductor die structures may be cut from the semiconductor wafer 100 without deviating from the scope of the present disclosure.

Each conjoined semiconductor die structure 352 may be similar to any of the conjoined semiconductor die structures described herein, such as the conjoined semiconductor die structure 116 (FIGS. 1-2C), the conjoined semiconductor die structure 200 (FIGS. 3A-3B), the conjoined semiconductor die structures 302 (FIG. 4), and/or the like. For instance, as shown, each conjoined semiconductor die structure 352 may include at least two semiconductor die 354. More particularly, each conjoined semiconductor die structure 302 may include a first semiconductor die 354-1, a second semiconductor die 354-2, and a third semiconductor die 354-3. Each semiconductor die 354 may be similar to any of the semiconductor die described herein, such as the semiconductor die 108 (FIGS. 1-2C), the semiconductor die 204 (FIGS. 3A-3B), the semiconductor die 304 (FIG. 4), and/or the like. In some examples, each semiconductor die 354 may include a metal-oxide-semiconductor field-effect transistor (MOSFET). Additionally and/or alternatively, in some examples, each semiconductor die 354 may include a Schottky diode. However, those having ordinary skill in the art, using the disclosures provided herein, will understand that the semiconductor die 354 may include any suitable semiconductor device without deviating from the scope of the present disclosure.

At 370, the method 350 may include obtaining die viability data associated with each of the plurality of conjoined semiconductor die structures 352 singulated from the semiconductor wafer 100. As noted above, die viability data refers to data that is indicative of an operability of each respective semiconductor die 354 of each of the plurality of conjoined semiconductor die structures 352. At 380, the method 350 may include packaging each of the plurality of conjoined semiconductor die structures 352 to form a power semiconductor device package 356 based on the die viability data obtained at 370.

By way of non-limiting illustrative example, at 370-1, die viability data may be obtained for each of the first semiconductor die 354-1, the second semiconductor die 354-2, and the third semiconductor die 354-3 of the conjoined semiconductor die structure 352-1. Based on the die viability data obtained at 370-1, the first semiconductor die 354-1, the second semiconductor die 354-2, and the third semiconductor die 354-3 may be determined to be active semiconductor die (e.g., functioning, non-defective, operational, etc.). As such, at 380-1, the conjoined semiconductor die structure 352-1 may be packaged to form a power semiconductor device package 356-1 such that each of the first semiconductor die 354-1, the second semiconductor die 354-2, and the third semiconductor die 354-3 are electrically coupled in the power semiconductor device package 356-1.

By way of another non-limiting illustrative example, at 370-2, die viability may be obtained may be obtained for each of the first semiconductor die 354-1, the second semiconductor die 354-2, and the third semiconductor die 354-3 of each of the conjoined semiconductor die structures 352-2-352-7. Based on the die viability data obtained at 370-2, at least one of the semiconductor die 354 may be determined to be an inactive semiconductor die (e.g., non-functioning, defective, non-operational, etc.) and at least one semiconductor die 304 may be determined to be an active semiconductor die (e.g., functioning, non-defective, operational, etc.).

For instance, in the conjoined semiconductor die structure 352-2, the first semiconductor die 354-1 and the second semiconductor die 354-2 may be active semiconductor die, and the third semiconductor die 354-3 may be an inactive semiconductor die. In the conjoined semiconductor die structure 352-3, the first semiconductor die 354-1 and the third semiconductor die 354-3 may be active semiconductor die, and the second semiconductor die 354-2 may be an inactive semiconductor die. In the conjoined semiconductor die structure 352-4, the second semiconductor die 354-2 and the third semiconductor die 354-3 may be active semiconductor die, and the first semiconductor die 354-1 may be an inactive semiconductor die. In the conjoined semiconductor die structure 352-5, the first semiconductor die 354-1 may be an active semiconductor die, and the second semiconductor die 354-2 and the third semiconductor die 354-3 may be inactive semiconductor die. In the conjoined semiconductor die structure 352-6, the second semiconductor die 354-2 may be an active semiconductor die, and the first semiconductor die 354-1 and the third semiconductor die 354-3 may be inactive semiconductor die. In the conjoined semiconductor die structure 352-7, the third semiconductor die 354-3 may be an active semiconductor die, and the first semiconductor die 354-1 and the second semiconductor die 354-2 may be inactive semiconductor die.

As such, at 380-2, each conjoined semiconductor die structure 352-2-352-7 may be packaged to form a power semiconductor device package 356-2 such that no current flows through the inactive semiconductor die during operation. More particularly, at 380-2A, each conjoined semiconductor die structure 352-2-352-4 may be packaged to form a power semiconductor device package 356-2A having two active semiconductor die and one inactive semiconductor die. For instance, the conjoined semiconductor die structure 352-2 may be packaged such that no current flows through the third semiconductor die 354-3 during operation, the conjoined semiconductor die structure 352-3 may be packaged such that no current flows through the second semiconductor die 354-2 during operation, and the conjoined semiconductor die structure 352-4 may be packaged such that no current flows through the first semiconductor die 354-1 during operation. Similarly, at 380-2B, each conjoined semiconductor die structure 352-5-352-7 may be packaged to form a power semiconductor device package 356-2B having one active semiconductor die and two inactive semiconductor die. For instance, the conjoined semiconductor die structure 352-5 may be packaged such that no current flows through the second semiconductor die 354-2 and/or the third semiconductor die 354-3 during operation, the conjoined semiconductor die structure 352-6 may be packaged such that no current flows through the first semiconductor die 354-1 and/or the third semiconductor die 354-3 during operation, and the conjoined semiconductor die structure 352-7 may be packaged such that no current flows through the first semiconductor die 354-1 and/or the second semiconductor die 354-2 during operation.

By way of another non-limiting illustrative example, at 370-3, die viability data may be obtained for each of the first semiconductor die 354-1, the second semiconductor die 354-2, and the third semiconductor die 354-3 of the conjoined semiconductor die structures 352-8. Based on the die viability data obtained at 370-3, each of the first semiconductor die 354-1, the second semiconductor die 354-2, and the third semiconductor die 354-3 may be determined to be inactive semiconductor die (e.g., non-functioning, defective, non-operational, etc.). As such, at 380-3, the conjoined semiconductor die structure 352-8 may be discarded in response to determining (at 370-3) that each semiconductor die 354 of the conjoined semiconductor die structure 352-8 are inactive semiconductor die.

FIGS. 4-5 depict example conjoined semiconductor die structures 302, 352 for purposes of illustration and discussion. Those having ordinary skill in the art, using the disclosures provided herein, will understand that different conjoined semiconductor die structure configurations may be used without deviating from the scope of the present disclosure. For instance, example aspects of the methods 300, 350 may be applied to conjoined semiconductor die structures having any suitable arrangement, configuration, number of semiconductor die, etc., without deviating from the scope of the present disclosure.

FIGS. 6A-6C depict top plan views of an example power semiconductor device package 400 according to example embodiments of the present disclosure. In some examples, the power semiconductor device package 400 may correspond to the power semiconductor device package 306 described above with reference to FIG. 4. It should be understood that FIGS. 6A-6C are intended to represent structures for purposes of identification and description and are not intended to represent the structures to physical scale.

As shown in FIGS. 6A-6C, the power semiconductor device package 400 may include a submount 402. The submount 402 may be similar to any of the submounts described herein. The power semiconductor device package 400 may further include a conjoined semiconductor die structure 404 on the submount 402. The conjoined semiconductor die structure 404 may be similar to any of the conjoined semiconductor die structures described herein. For instance, the conjoined semiconductor die structure 404 may include a first semiconductor die 406-1 and a second semiconductor die 406-2 (collectively “semiconductor die 406”). The semiconductor die 406 may include a common substrate (not shown). It should be understood that the conjoined semiconductor die structure 404 may include more than two semiconductor die 406 without deviating from the scope of the present disclosure. The power semiconductor device package 400 may further include an encapsulating material around at least a portion of the submount 402 and the conjoined semiconductor die structure 404 that forms a housing 408. Hence, the housing 408 may at least partially encapsulate the submount 402 and the conjoined semiconductor die structure 404.

In the examples depicted in FIGS. 6A-6C, each of the semiconductor die 406 include a MOSFET. More particularly, as shown, the first semiconductor die 406-1 may include a source contact 410 and a gate contact 412 on a first side 404A of the conjoined semiconductor die structure 404. The first semiconductor die 406-1 may further include a drain contact (not shown) on a second side (not shown) of the conjoined semiconductor die structure 404 that is opposite the first side 404A. In some examples, the drain contact (not shown) of the first semiconductor die 406-1 may be similar to the backside metallization structure 120 described above (e.g., FIGS. 2A-2C). Likewise, the second semiconductor die 406-2 may include a source contact 410 and a gate contact 412 on the first side 404A of the conjoined semiconductor die structure 404. The second semiconductor die 406-2 may further include a drain contact (not shown) on the second side (not shown) of the conjoined semiconductor die structure 404. In some examples, the drain contact (not shown) of the second semiconductor die 406-2 may be similar to the backside metallization structure 120 described above (e.g., FIGS. 2A-2C).

As described herein, the power semiconductor device package 400 may be formed based on die-viability data associated with each of the semiconductor die 406 of the conjoined semiconductor die structure 404.

In some examples, such as that depicted in FIG. 6A, the die-viability data may indicate that both the first semiconductor die 406-1 and the second semiconductor die 406-2 are an active semiconductor die (e.g., functioning, non-defective, operational, etc.). In such examples, the first semiconductor die 406-1 and the second semiconductor die 406-2 may be electrically coupled in the conjoined semiconductor die structure 404. As such, current may flow through each of the first semiconductor die 406-1 and the second semiconductor die 406-2 during operation of the power semiconductor device package 400. For instance, as shown in FIG. 6A, the source contact 410 of the first semiconductor die 406-1 may be electrically coupled to the source contact 410 of the second semiconductor die 406-2, and the gate contact 412 of the first semiconductor die 406-1 may be electrically coupled to the gate contact 412 of the second semiconductor die 406-2. In some examples, the conjoined semiconductor die structure 404 may include one or more electrical connectors 414 (e.g., wire bond(s), ribbon bond(s), etc.) that electrically couple the first semiconductor die 406-1 and the second semiconductor die 406-2.

In some examples, such as that depicted in FIGS. 6B-6C, the die-viability data may indicate that one of the first semiconductor die 406-1 or the second semiconductor die 406-2 of the conjoined semiconductor die structure 404 is an inactive semiconductor die (e.g., non-functioning, defective, non-operational, etc.), while the other of the first semiconductor die 406-1 or the second semiconductor die 406-2 is an active semiconductor die (e.g., functioning, non-defective, operational, etc.). In such examples, in contrast to the example described above with reference to FIG. 6A, the first semiconductor die 406-1 and the second semiconductor die 406-2 are not electrically coupled in the conjoined semiconductor die structure 404 and, instead, are configured such that no current flows through the inactive semiconductor die (e.g., one of the first semiconductor die 406-1 or the second semiconductor die 406-2) during operation of the power semiconductor device package 400.

For instance, in the example depicted in FIG. 6B, the first semiconductor die 406-1 is an active semiconductor die (e.g., functioning, non-defective, operational, etc.), while the second semiconductor die 406-2 is an inactive semiconductor die (e.g., non-functioning, defective, non-operational). As such, no current may flow through the second semiconductor die 406-2 during operation of the power semiconductor device package 400. In this manner, the second semiconductor die 406-2 may be configured to provide a heat dissipation path for the conjoined semiconductor die structure 404. Additionally and/or alternatively, in the example depicted in FIG. 6C, the second semiconductor die 406-2 is an active semiconductor die (e.g., functioning, non-defective, operational, etc.), while the first semiconductor die 406-1 is an inactive semiconductor die (e.g., non-functioning, defective, non-operational). As such, no current may flow through the first semiconductor die 406-1 during operation of the power semiconductor device package 400. In this manner, the first semiconductor die 406-1 may be configured to provide a heat dissipation path for the conjoined semiconductor die structure 404.

Referring again to FIGS. 6A-6C, in some examples, the power semiconductor device package 400 may further include a plurality of electrical leads 416 extending from the housing 408. More particularly, the plurality of electrical leads 416 may include a source lead 416-1, a gate lead 416-2, and a drain lead 416-3. It should be understood that the power semiconductor device package 400 may include more than three electrical leads 416 without deviating from the scope of the present disclosure. For instance, in some examples, the plurality of electrical leads 416 may further include a source-kelvin lead, a sensor lead, and/or the like.

The source lead 416-1 of the plurality of electrical leads 416 may be coupled to a source structure of the conjoined semiconductor die structure 404. As used herein, a “source structure” refers to the source contact(s) of the active semiconductor die. For instance, in the example depicted in FIG. 6A, the source structure refers to both the source contact 410 of the first semiconductor die 406-1 and the source contact 410 of the second semiconductor die 406-2. As shown, the source contact 410 of the first semiconductor die 406-1 is electrically coupled to the source contact 410 of the second semiconductor die 406-2 (e.g., via an electrical connector 414) in a parallel configuration, and the source contact 410 of the second semiconductor die 406-2 is electrically coupled to the source lead 416-1 (e.g., via an electrical connector 414). As will be discussed in greater detail below, in some examples (e.g., FIG. 9), each source contact 410 of the semiconductor die 406 may be individually coupled to the source lead 416-1 (e.g., via individual electrical connectors 414) without deviating from the scope of the present disclosure.

Additionally and/or alternatively, in the example depicted in FIG. 6B, the source structure refers to the source contact 410 of the first semiconductor die 406-1. As shown, the source contact 410 of the first semiconductor die 406-1 is electrically coupled to the source lead 416-1 (e.g., via an electrical connector 414). However, because the second semiconductor die 406-2 is an inactive semiconductor die, the source contact 410 of the second semiconductor die 406-2 is not electrically coupled to the source lead 416-1.

Additionally and/or alternatively, in the example depicted in FIG. 6C, the source structure refers to the source contact 410 of the second semiconductor die 406-2. As shown, the source contact 410 of the second semiconductor die 406-2 is electrically coupled to the source lead 416-1 (e.g., via an electrical connector 414). However, because the first semiconductor die 406-1 is an inactive semiconductor die, the source contact 410 of the first semiconductor die 406-1 is not electrically coupled to the source lead 416-1.

The gate lead 416-2 of the plurality of electrical leads 416 may be coupled to a gate structure of the conjoined semiconductor die structure 404. As used herein, a “gate structure” refers to the gate contact(s) of the active semiconductor die. For instance, in the example depicted in FIG. 6A, the gate structure refers to both the gate contact 412 of the first semiconductor die 406-1 and the gate contact 412 of the second semiconductor die 406-2. As shown, the gate contact 412 of the first semiconductor die 406-1 is electrically coupled to the gate contact 412 of the second semiconductor die 406-2 (e.g., via an electrical connector 414) in a parallel configuration, and the gate contact 412 of the second semiconductor die 406-2 is electrically coupled to the gate lead 416-2 (e.g., via an electrical connector 414). As will be discussed in greater detail below, in some examples (e.g., FIG. 9), each gate contact 412 of the semiconductor die 406 may be individually coupled to the gate lead 416-2 without deviating from the scope of the present disclosure.

Additionally and/or alternatively, in the example depicted in FIG. 6B, the gate structure refers to the gate contact 412 of the first semiconductor die 406-1. As shown, the gate contact 412 of the first semiconductor die 406-1 is electrically coupled to the gate lead 416-2 (e.g., via an electrical connector 414). However, because the second semiconductor die 406-2 is an inactive semiconductor die, the gate contact 412 of the second semiconductor die 406-2 is not electrically coupled to the gate lead 416-2.

Additionally and/or alternatively, in the example depicted in FIG. 6C, the gate structure refers to the gate contact 412 of the second semiconductor die 406-2. As shown, the gate contact 412 of the second semiconductor die 406-2 is electrically coupled to the gate lead 416-2 (e.g., via an electrical connector 414). However, because the first semiconductor die 406-1 is an inactive semiconductor die, the gate contact 412 of the first semiconductor die 406-1 is not electrically coupled to the gate lead 416-2.

The drain lead 416-3 of the plurality of electrical leads 416 may be coupled to a drain structure of the conjoined semiconductor die structure 404. As described above, the conjoined semiconductor die structure 404 may include a common substrate (not shown) on a second side (not shown) of the conjoined semiconductor die structure 404, and a drain contact (e.g., backside metallization structure 120 (FIGS. 2A-2C)) of the first semiconductor die 406-1 and the second semiconductor die 406-2 may be coupled to the common substrate (not shown). In some examples such as that depicted in FIGS. 6A-6C, the submount 402 may be and/or may include a lead frame. In such examples, the drain lead 416-3 may be coupled to the lead frame (e.g., to the submount 402).

FIGS. 6A-6C depict example semiconductor packages for purposes of illustration and discussion. Those having ordinary skill in the art, using the disclosures provided herein, will understand that different semiconductor package configurations may be used without deviating from the scope of the present disclosure.

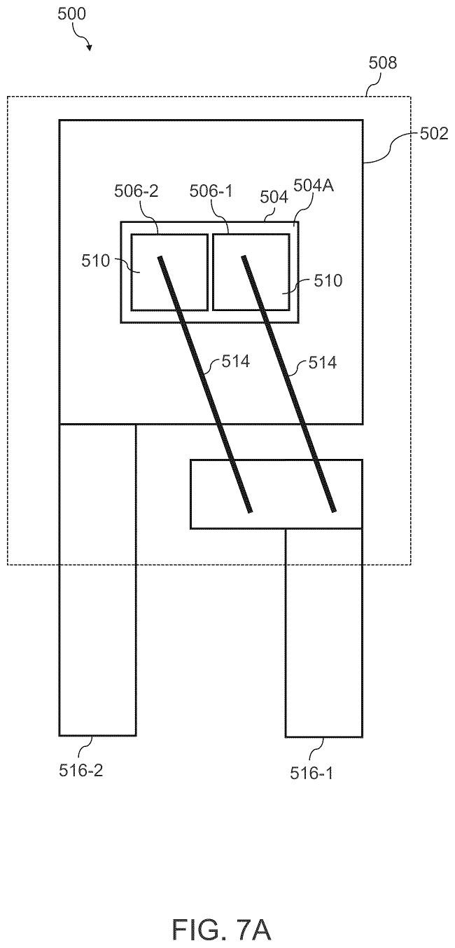

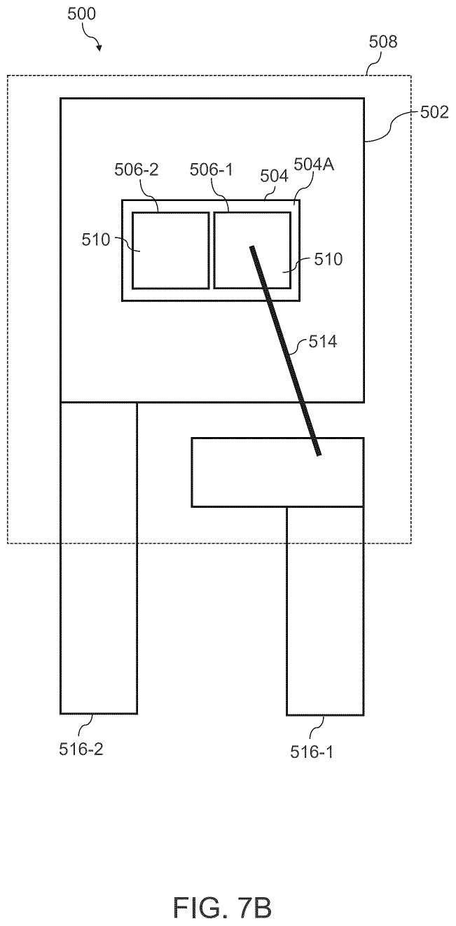

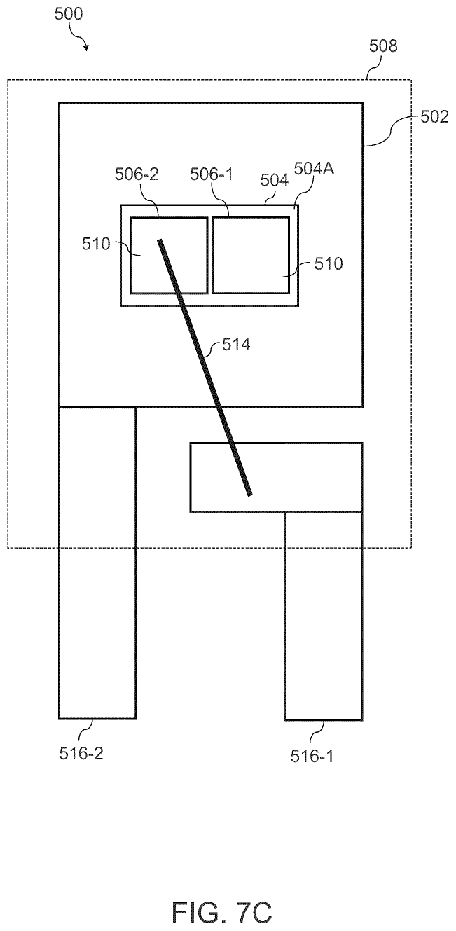

FIGS. 7A-7C depict top plan views of an example power semiconductor device package 500 according to example embodiments of the present disclosure. In some examples, the power semiconductor device package 500 may correspond to the power semiconductor device package 306 described above with reference to FIG. 4. It should be understood that FIGS. 7A-7C are intended to represent structures for purposes of identification and description and are not intended to represent the structures to physical scale.

As shown in FIGS. 7A-7C, the power semiconductor device package 500 may include a submount 502. The submount 502 may be similar to any of the submounts described herein. The power semiconductor device package 500 may further include a conjoined semiconductor die structure 504 on the submount 502. The conjoined semiconductor die structure 404 may be similar to any of the conjoined semiconductor die structures described herein. For instance, the conjoined semiconductor die structure 504 may include a first semiconductor die 506-1 and a second semiconductor die 506-2 (collectively “semiconductor die 506”). The semiconductor die 506 may include a common substrate (not shown). It should be understood that the conjoined semiconductor die structure 504 may include more than two semiconductor die 506 without deviating from the scope of the present disclosure. The power semiconductor device package 500 may further include an encapsulating material around at least a portion of the submount 502 and the conjoined semiconductor die structure 504 that forms a housing 508. Hence, the housing 508 may at least partially encapsulate the submount 502 and the conjoined semiconductor die structure 504.

In the examples depicted in FIGS. 7A-7C, each of the semiconductor die 506 may include a Schottky diode. More particularly, as shown, the first semiconductor die 506-1 may include an anode contact 510 on a first side 504A of the conjoined semiconductor die structure 504. The first semiconductor die 506-1 may further include a cathode contact (not shown) on a second side (not shown) of the conjoined semiconductor die structure 504 that is opposite the first side 504A. In some examples, the cathode contact (not shown) of the first semiconductor die 506-1 may be similar to the backside metallization structure 120 described above (e.g., FIGS. 2A-2C). Likewise, the second semiconductor die 506-2 may include an anode contact 510 on the first side 504A of the conjoined semiconductor die structure 504. The second semiconductor die 506-2 may further include a cathode contact (not shown) on the second side (not shown) of the conjoined semiconductor die structure 504 that is opposite the first side 504A. In some examples, the cathode contact (not shown) of the second semiconductor die 506-2 may be similar to the backside metallization structure 120 described above (e.g., FIGS. 2A-2C).

It should be understood that the anode contacts 510 and the cathode contacts (not shown) are described as being on the first side 504A and the second side (not shown), respectively, of the conjoined semiconductor die structure 504 for purposes of illustration and discussion. Those having ordinary skill in the art, using the disclosures provided herein, will understand that the cathode contacts (not shown) may be on the first side 504A and the anode contacts 510 may be on the second side (not shown) without deviating from the scope of the present disclosure. For instance, by way of non-limiting example, an example semiconductor die of the present disclosure (e.g., semiconductor die 506) may include a cathode contact on the first side 504A and an anode contact on the second side (not shown). In such examples, the anode contact may be similar to the backside metallization structure 120 described above (e.g., FIGS. 2A-2C).

As described herein, the power semiconductor device package 500 may be formed based on die-viability data associated with each of the semiconductor die 506 of the conjoined semiconductor die structure 404.

In some examples, such as that depicted in FIG. 7A, the die-viability data may indicate that both the first semiconductor die 506-1 and the second semiconductor die 506-2 are an active semiconductor die (e.g., functioning, non-defective, operational, etc.). In such examples, the first semiconductor die 506-1 and the second semiconductor die 506-2 may be electrically coupled in the conjoined semiconductor die structure 504. As such, current may flow through each of the first semiconductor die 506-1 and the second semiconductor die 506-2 during operation of the power semiconductor device package 500. For instance, as shown in FIG. 7A, the anode contact 510 of the first semiconductor die 506-1 may be electrically coupled to the anode contact 510 of the second semiconductor die 506-2. In some examples, the conjoined semiconductor die structure 504 may include one or more electrical connectors 514 (e.g., wire bond(s), ribbon bond(s), etc.) that electrically couple the first semiconductor die 506-1 and the second semiconductor die 506-2.

In some examples, such as that depicted in FIGS. 7B-7C, the die-viability data may indicate that one of the first semiconductor die 506-1 or the second semiconductor die 506-2 of the conjoined semiconductor die structure 504 is an inactive semiconductor die (e.g., non-functioning, defective, non-operational, etc.), while the other of the first semiconductor die 506-1 or the second semiconductor die 506-2 is an active semiconductor die (e.g., functioning, non-defective, operational, etc.). In such examples, in contrast to the example described above with reference to FIG. 7A, the first semiconductor die 506-1 and the second semiconductor die 506-2 are not electrically coupled in the conjoined semiconductor die structure 504 and, instead, are configured such that no current flows through the inactive semiconductor die (e.g., one of the first semiconductor die 506-1 or the second semiconductor die 506-2) during operation of the power semiconductor device package 500.

For instance, in the example depicted in FIG. 7B, the first semiconductor die 506-1 is an active semiconductor die (e.g., functioning, non-defective, operational, etc.), while the second semiconductor die 506-2 is an inactive semiconductor die (e.g., non-functioning, defective, non-operational). As such, no current may flow through the second semiconductor die 506-2 during operation of the power semiconductor device package 500. In this manner, the second semiconductor die 506-2 may be configured to provide a heat dissipation path for the conjoined semiconductor die structure 504. Additionally and/or alternatively, in the example depicted in FIG. 7C, the second semiconductor die 506-2 is an active semiconductor die (e.g., functioning, non-defective, operational, etc.), while the first semiconductor die 506-1 is an inactive semiconductor die (e.g., non-functioning, defective, non-operational). As such, no current may flow through the first semiconductor die 506-1 during operation of the power semiconductor device package 500. In this manner, the first semiconductor die 506-1 may be configured to provide a heat dissipation path for the conjoined semiconductor die structure 504.

Referring again to FIGS. 7A-7C, in some examples, the power semiconductor device package 500 may further include a plurality of electrical leads 516 extending from the housing 508. More particularly, the plurality of electrical leads 516 may include an anode lead 516-1 and a cathode lead 516-2. It should be understood that the power semiconductor device package 500 may include more than three electrical leads 516 without deviating from the scope of the present disclosure.

The anode lead 516-1 of the plurality of electrical leads 516 may be coupled to an anode structure of the conjoined semiconductor die structure 504. As used herein, an “anode structure” refers to the anode contact(s) of the active semiconductor die. For instance, in the example depicted in FIG. 7A, the anode structure refers to both the anode contact 510 of the first semiconductor die 506-1 and the anode contact 510 of the second semiconductor die 506-2. As shown, the anode contact 510 of the first semiconductor die 506-1 is electrically coupled to the anode contact 510 of the second semiconductor die 506-2 (e.g., via an electrical connector 514) in a parallel configuration, and the anode contact 510 of the second semiconductor die 506-2 is electrically coupled to the anode lead 516-1 (e.g., via an electrical connector 514). As will be discussed in greater detail below, in some examples (e.g., FIG. 9), each anode contact 510 of the semiconductor die 506 may be individually coupled to the anode lead 516-1 without deviating from the scope of the present disclosure.

Additionally and/or alternatively, in the example depicted in FIG. 7B, the anode structure refers to the anode contact 510 of the first semiconductor die 506-1. As shown, the anode contact 510 of the first semiconductor die 506-1 is electrically coupled to the anode lead 516-1 (e.g., via an electrical connector 514). However, because the second semiconductor die 506-2 is an inactive semiconductor die, the anode contact 510 of the second semiconductor die 506-2 is not electrically coupled to the anode lead 516-1.

Additionally and/or alternatively, in the example depicted in FIG. 7C, the anode structure refers to the anode contact 510 of the second semiconductor die 506-2. As shown, the anode contact 510 of the second semiconductor die 506-2 is electrically coupled to the anode lead 516-1 (e.g., via an electrical connector 514). However, because the first semiconductor die 506-1 is an inactive semiconductor die, the anode contact 510 of the first semiconductor die 506-1 is not electrically coupled to the anode lead 516-1.

The cathode lead 516-2 of the plurality of electrical leads 516 may be coupled to a cathode structure of the conjoined semiconductor die structure 504. As described above, the conjoined semiconductor die structure 504 may include a common substrate (not shown) on a second side (not shown) of the conjoined semiconductor die structure 504, and a cathode contact (e.g., backside metallization structure 120 (FIGS. 2A-2C)) of the first semiconductor die 506-1 and the second semiconductor die 506-2 may be coupled to the common substrate (not shown). In some examples such as that depicted in FIGS. 7A-7C, the submount 502 may be and/or may include a lead frame. In such examples, the cathode lead 516-2 may be coupled to the lead frame (e.g., to the submount 502).

FIGS. 7A-7C depict example semiconductor packages for purposes of illustration and discussion. Those having ordinary skill in the art, using the disclosures provided herein, will understand that different semiconductor package configurations may be used without deviating from the scope of the present disclosure.

FIGS. 8A-8D depict top plan views of an example power semiconductor device package 600 according to example embodiments of the present disclosure. In some examples, the power semiconductor device package 600 may correspond to the power semiconductor device package 306 described above with reference to FIG. 4. It should be understood that FIGS. 8A-8D are intended to represent structures for purposes of identification and description and are not intended to represent the structures to physical scale.

As shown in FIGS. 8A-8D, the power semiconductor device package 600 may be similar to the power semiconductor device package 400 described above with reference to FIGS. 6A-6C. For instance, the power semiconductor device package 600 may include a submount 602, which may be similar to any of the submounts described herein. The power semiconductor device package 600 may further include a conjoined semiconductor die structure 604 on the submount 602. The conjoined semiconductor die structure 604 may be similar to any of the conjoined semiconductor die structures described herein. For instance, the conjoined semiconductor die structure 604 may include a first semiconductor die 606-1 and a second semiconductor die 606-2 (collectively “semiconductor die 606”). The semiconductor die 606 may include a common substrate (not shown). It should be understood that the conjoined semiconductor die structure 604 may include more than two semiconductor die 606 without deviating from the scope of the present disclosure. The power semiconductor device package 600 may further include an encapsulating material around at least a portion of the submount 602 and the conjoined semiconductor die structure 604 that forms a housing 608. Hence, the housing 608 may at least partially encapsulate the submount 602 and the conjoined semiconductor die structure 604.

Furthermore, in the examples depicted in FIGS. 8A-8D, each of the semiconductor die 606 may include a MOSFET. More particularly, as shown, each of the first semiconductor die 606-1 and the second semiconductor die 606-2 may include a source contact 610 on a first side 604A of the conjoined semiconductor die structure 604. Each of the first semiconductor die 606-1 and the second semiconductor die 606-2 may also include a drain contact (not shown) on a second side (not shown) of the conjoined semiconductor die structure 604 that is opposite the first side 604A. As described above, the drain contact (not shown) of the first semiconductor die 604-1 and the second semiconductor die 606-2 may be similar to the backside metallization structure 120 described above (e.g., FIGS. 2A-2C). However, in contrast to the semiconductor die 406 described above with reference to FIGS. 6A-6C, a gate contact 612 of the first semiconductor die 606-1 may include two gate pads 612A, 612B, and a gate contact 612 of the second semiconductor die 606-2 may include two gate pads 612A, 612B. As shown, each of the at least two gate pads 612A, 612B of each of the first semiconductor die 606-1 and the second semiconductor die 606-2 are on the first side 604A of the conjoined semiconductor die structure 604. In this way, as will be discussed in greater detail below, the conjoined semiconductor die structure 604 (e.g., the source contact 610 and each of the at least two gate pads 612A, 612B) may be symmetrical when rotated approximately 180-degrees about an axis of rotation R (e.g., when rotated approximately 180-degrees about a housing plane H defined by the housing 608).

The power semiconductor device package 600 may be packaged based on the die-viability data associated with the first semiconductor die 606-1 and the second semiconductor die 606-2 in a similar manner as set forth above (e.g., FIGS. 6A-6C) with reference to the first semiconductor die 404-1 and the second semiconductor die 404-2, respectively. For instance, in the example depicted in FIG. 8A, the power semiconductor device package 600 may be packaged based on die viability data indicating that the first semiconductor die 606-1 and the second semiconductor die 606-2 are active semiconductor die. In the example depicted in FIG. 8B, the power semiconductor device package 600 may be packaged based on die viability data indicating that the first semiconductor die 606-1 is an active semiconductor die and the second semiconductor die 606-2 is an inactive semiconductor die. In the example depicted in FIGS. 8C-8D, the power semiconductor device package 600 may be packaged based on die viability data indicating that the first semiconductor die 606-1 is an inactive semiconductor die and the second semiconductor die 606-2 is an active semiconductor die.

Furthermore, the power semiconductor device package 600 may also include a plurality of electrical leads 616 extending from the housing 608. More particularly, the plurality of electrical leads 616 may include a source lead 616-1, a gate lead 616-2, and a drain lead 616-3. However, in contrast to the plurality of electrical leads 416 described above with reference to FIGS. 6A-6C, the plurality of electrical leads 616 may further include an additional lead 616-4. It should be understood that the power semiconductor device package 600 may include more than four electrical leads 616 without deviating from the scope of the present disclosure.

The conjoined semiconductor die structure 604 may be coupled to the plurality of electrical leads 616 in a similar manner as set forth above (e.g., FIGS. 6A-6C) with reference to the conjoined semiconductor die structure 404 and the plurality of electrical leads 416. For instance, the source lead 616-1 may be coupled to a source structure of the conjoined semiconductor die structure 604 (e.g., via electrical connector(s) 614), the gate lead 616-2 may be coupled to a gate structure of the conjoined semiconductor die structure 604 (e.g., via electrical connector(s) 614), and the drain lead 616-3 may be coupled to a drain structure of the conjoined semiconductor die structure 604. Furthermore, the additional lead 616-4 may be coupled to an additional structure. As a non-limiting illustrative example, the additional lead 616-4 is depicted in FIGS. 8A-8D as being coupled to the source structure (e.g., the source lead 610 of one of the first semiconductor die 606-1 and/or the second semiconductor die 606-2). Those having ordinary skill in the art, using the disclosures provided herein, will understand that the additional lead 616-4 may be coupled to other semiconductor structures, contacts, etc., without deviating from the scope of the present disclosure.

As noted above, the conjoined semiconductor die structure 604 depicted in FIGS. 8A-8D may be symmetrical when rotated approximately 180-degrees about the axis of rotation R due the orientation of the source contact 610 and the two gate pads 612A, 612B of each semiconductor die 606. More particularly, as shown, each semiconductor die 606 may be disposed between each of the gate pads 612A, 612B. Put differently, the gate pad 612A and the gate pad 612B may (respectively) be adjacent to opposing ends of the source contact 610 such that, when rotated approximately 180-degrees about the axis of rotation R (e.g., about the housing plane H), the configuration (e.g., layout) of the gate pads 612A, 612B and the source contact 610 is symmetrical.

As an illustrative example, FIGS. 8C-8D depict the same power semiconductor device package 600, except the conjoined semiconductor die structure 604 of FIG. 8D is rotated 180-degrees about the axis of rotation R relative to the conjoined semiconductor die structure 604 depicted in FIG. 8C. That is, the conjoined semiconductor die structure 604 may be rotated during packaging of the power semiconductor device package 600 depicted in FIG. 8D such that the orientation of the semiconductor die 606 on the conjoined semiconductor die structure 604 (and a length of the electrical connectors 614) is similar to that of the conjoined semiconductor die structure 604 (and the electrical connectors 614) depicted in FIG. 8B.

FIGS. 8A-8D depict example semiconductor packages for purposes of illustration and discussion. Those having ordinary skill in the art, using the disclosures provided herein, will understand that different semiconductor package configurations may be used without deviating from the scope of the present disclosure.

As noted above, in some examples, each semiconductor die of an example conjoined semiconductor die structure of the present disclosure may be individually coupled to a corresponding electrical lead. As an illustrative example, FIG. 9 depicts a top plan view of an example power semiconductor device package 700 according to example embodiments of the present disclosure. In some examples, the power semiconductor device package 700 may correspond to the power semiconductor device package 306 described above with reference to FIG. 4. It should be understood that FIG. 9 is intended to represent structures for purposes of identification and description and is not intended to represent the structures to physical scale.

The power semiconductor device package 700 depicted in FIG. 9 may be similar to the power semiconductor device package 400 described above with reference to FIGS. 6A-6C. For instance, as shown, the power semiconductor device package 700 may include a submount 702 and a conjoined semiconductor die structure 704 on the submount 702. The conjoined semiconductor die structure 704 may include a first semiconductor die 706-1 and a second semiconductor die 706-2 (collectively, “semiconductor die 706) having common substrate (not shown), and each of the semiconductor die 706 may include a MOSFET. As shown, each semiconductor die 706 may include a source contact 710 and a gate contact 712 on a first side 704A of the conjoined semiconductor die structure 704; each semiconductor die 706 may also include a drain contact (not shown) on a second side (not shown) of the conjoined semiconductor die structure 704 that is opposite the first side 704A. Each semiconductor die 706 and its corresponding contacts (e.g., source contact 710, gate contact 712, drain contact (not shown)) may be similar to that described above with reference to FIGS. 6A-6C. It should be understood that the conjoined semiconductor die structure 704 may include more than two semiconductor die 706 without deviating from the scope of the present disclosure.

The power semiconductor device package 700 may be packaged based on the die-viability data associated with the first semiconductor die 706-1 and the second semiconductor die 706-2 in a similar manner as set forth above (e.g., FIGS. 6A-6C) with reference to the first semiconductor die 404-1 and the second semiconductor die 404-2, respectively.

The power semiconductor device package 700 may further include an encapsulating material around at least a portion of the submount 702 and the conjoined semiconductor die structure 704 that forms a housing 708. Hence, the housing 708 may at least partially encapsulate the submount 702 and the conjoined semiconductor die structure 704. The power semiconductor device package 700 may further include a plurality of electrical leads 716 extending from the housing 708. For instance, as shown, the power semiconductor device package 700 may include a source lead 716-1, a gate lead 716-2, and a drain lead 716-3. Each of the plurality of electrical leads 716 may be similar to that described above with reference to FIGS. 6A-6C. It should be understood that the power semiconductor device package 700 may include more than three electrical leads 716 without deviating from the scope of the present disclosure.

The conjoined semiconductor die structure 704 may be coupled to the plurality of electrical leads 716 in a similar manner as set forth above (e.g., FIGS. 6A-6C) with reference to the conjoined semiconductor die structure 404 and the plurality of electrical leads 416. For instance, the source lead 716-1 may be coupled to a source structure of the conjoined semiconductor die structure 704, the gate lead 716-2 may be coupled to a gate structure of the conjoined semiconductor die structure 704, and the drain lead 716-3 may be coupled to a drain structure of the conjoined semiconductor die structure 704.

In the example depicted in FIG. 9, the power semiconductor device package 700 may be packaged based on die viability data that indicates both the first semiconductor die 706-1 and the second semiconductor die 706-2 are active semiconductor die. However, in contrast to the power semiconductor device package 400 described above with reference to FIG. 6A, each source contact 710 of each semiconductor die 706 may be individually coupled to the source lead 716-1, and each gate contact 712 of each semiconductor die 706 may be individually coupled to the gate lead 716-2. More particularly, the first semiconductor die 706-1 may be coupled to the plurality of electrical leads 716 via a first plurality of electrical connectors 714A, and the second semiconductor die 706-2 may be coupled to the plurality of electrical leads 716 via a second plurality of electrical connectors 714B. As shown, the second plurality of electrical connectors 714B are different from the first plurality of electrical connectors 714A.

For instance, as shown, the source contact 710 of the first semiconductor die 706-1 may be coupled to the source lead 716-1 via one of the first plurality of electrical connectors 714A, and the source contact 710 of the second semiconductor die 706-2 may be coupled to the source lead 716-1 via one of the second plurality of electrical connectors 714B.

Likewise, the gate contact 712 of the first semiconductor die 706-1 may be coupled to the gate lead 716-2 via one of the first plurality of electrical connectors 714A, and the gate contact 712 of the second semiconductor die 706-2 may be coupled to the gate lead 716-2 via one of the second plurality of electrical connectors 714B. Hence, the first semiconductor die 706-1 and the second semiconductor die 706-2 may be individually coupled to a corresponding electrical lead 716 via different electrical connectors.

It should be understood that the electrical connections depicted in FIG. 9 are not limited to power semiconductor device packages having conjoined semiconductor die structures with MOSFETs. Those having ordinary skill in the art, using the disclosures provided herein, will understand that the electrical connections depicted in FIG. 9 may be used in power semiconductor device packages having conjoined semiconductor die structures with any suitable semiconductor device(s) without deviating from the scope of the present disclosure.

As described herein, example aspects of the present disclosure are not limited to conjoined semiconductor die structures having two semiconductor die. In some examples, example conjoined semiconductor die structures of the present disclosure may include at least three semiconductor die. For instance, FIG. 10 depicts a top plan view of an example power semiconductor device package 800 according to example embodiments of the present disclosure. In some examples, the power semiconductor device package 800 may correspond to the power semiconductor device packages 356 described above with reference to FIG. 5. It should be understood that FIG. 10 is intended to represent structures for purposes of identification and description and is not intended to represent the structures to physical scale.

The power semiconductor device package 800 may be similar to any of the power semiconductor device packages described herein. For instance, as shown in FIG. 10, the power semiconductor device package 800 may include a submount 802 and a conjoined semiconductor die structure 804 on the submount 802. In the example depicted in FIG. 10, however, the conjoined semiconductor die structure 804 includes at least three semiconductor die 806 that each include a common substrate (not shown). More particularly, as shown, the conjoined semiconductor die structure 804 may include a first semiconductor die 806-1, a second semiconductor die 806-2, and a third semiconductor die 806-3.

Furthermore, each semiconductor die 806 may include a MOSFET. For instance, as shown, each semiconductor die 806 source contact 810 and a gate contact 812 on a first side 804A of the conjoined semiconductor die structure 804; each semiconductor die 806 may also include a drain contact (not shown) on a second side (not shown) of the conjoined semiconductor die structure 804 that is opposite the first side 804A. Each semiconductor die 806 and its corresponding contacts (e.g., source contact 810, gate contact 812, drain contact (not shown)) may be similar to any semiconductor die described herein that also includes a MOSFET. Those having ordinary skill in the art, however, will understand that the semiconductor die 806 may include any suitable semiconductor device (e.g., Schottky diode(s), HEMT device(s), etc.) without deviating from the scope of the present disclosure.

The power semiconductor device package 800 may further include an encapsulating material around at least a portion of the submount 802 and the conjoined semiconductor die structure 804 that forms a housing 808. The power semiconductor device package 800 may further include a plurality of electrical leads 816 extending from the housing 808. For instance, as shown, the power semiconductor device package 800 may include a source lead 816-1, a gate lead 816-2, and a drain lead 816-3. Each of the plurality of electrical leads 816 may be similar to any other electrical lead described herein. It should be understood that the power semiconductor device package 800 may include more than three electrical leads 816 without deviating from the scope of the present disclosure.

The power semiconductor device package 800 may be packaged based on the die-viability data associated with the semiconductor die 806 in any suitable manner, such as any of the methods described herein. In the example depicted in FIG. 10, the power semiconductor device package 800 may be packaged based on die viability data that indicates each semiconductor die 806 of the conjoined semiconductor die structure 804 is an active semiconductor die. Hence, in such examples, the third semiconductor die 806-3 may be electrically coupled with the first semiconductor die 806-1 and the second semiconductor die 806-2. Furthermore, the conjoined semiconductor die structure 804 may be coupled to the plurality of electrical leads 816 in any suitable manner, such as any of the methods described herein. Those having ordinary skill in the art, using the disclosures provided herein, will understand that the power semiconductor device package 800 and the conjoined semiconductor die structure 804 may have any of the arrangements and/or configurations described herein and/or any variation thereof.

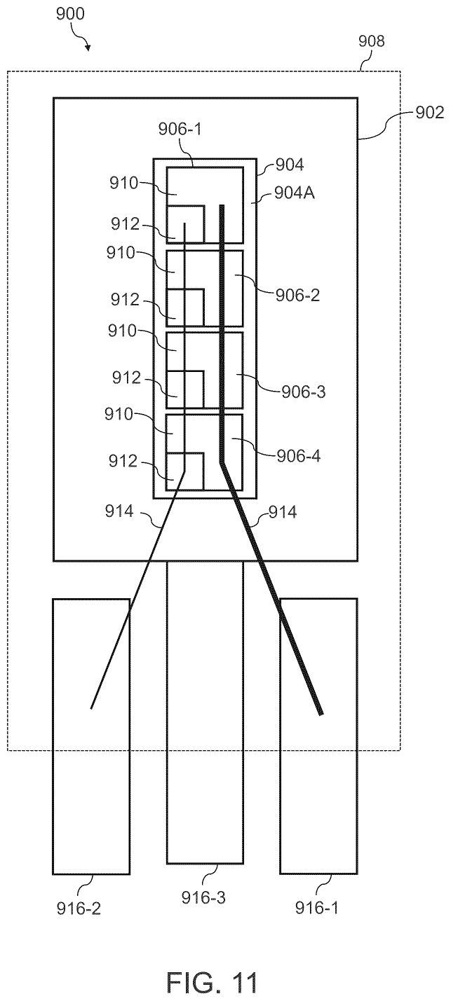

In some examples, example conjoined semiconductor die structures of the present disclosure may include four or more semiconductor die. For instance, FIG. 11 depicts a top plan view of an example power semiconductor device package 900 according to example embodiments of the present disclosure. It should be understood that FIG. 11 is intended to represent structures for purposes of identification and description and is not intended to represent the structures to physical scale.

The power semiconductor device package 900 may be similar to any of the power semiconductor device packages described herein. For instance, as shown in FIG. 11, the power semiconductor device package 900 may include a submount 902 and a conjoined semiconductor die structure 904 on the submount 902. In the example depicted in FIG. 11, however, the conjoined semiconductor die structure 904 includes at least four semiconductor die 906 that each include a common substrate (not shown). More particularly, as shown, the conjoined semiconductor die structure 904 may include a first semiconductor die 906-1, a second semiconductor die 906-2, a third semiconductor die 906-3, and a fourth semiconductor die 906-4.

Furthermore, each semiconductor die 906 may include a MOSFET. For instance, as shown, each semiconductor die 906 source contact 910 and a gate contact 912 on a first side 904A of the conjoined semiconductor die structure 904; each semiconductor die 906 may also include a drain contact (not shown) on a second side (not shown) of the conjoined semiconductor die structure 904 that is opposite the first side 904A. Each semiconductor die 906 and its corresponding contacts (e.g., source contact 910, gate contact 912, drain contact (not shown)) may be similar to any semiconductor die described herein that also includes a MOSFET. Those having ordinary skill in the art, however, will understand that the semiconductor die 906 may include any suitable semiconductor device (e.g., Schottky diode(s), HEMT device(s), etc.) without deviating from the scope of the present disclosure.

The power semiconductor device package 900 may further include an encapsulating material around at least a portion of the submount 902 and the conjoined semiconductor die structure 904 that forms a housing 908. The power semiconductor device package 900 may further include a plurality of electrical leads 916 extending from the housing 908. For instance, as shown, the power semiconductor device package 900 may include a source lead 916-1, a gate lead 916-2, and a drain lead 916-3. Each of the plurality of electrical leads 916 may be similar to any other electrical lead described herein. It should be understood that the power semiconductor device package 900 may include more than three electrical leads 916 without deviating from the scope of the present disclosure.

The power semiconductor device package 900 may be packaged based on the die-viability data associated with the semiconductor die 906 in any suitable manner, such as any of the methods described herein. In the example depicted in FIG. 11, the power semiconductor device package 900 may be packaged based on die viability data that indicates each semiconductor die 906 of the conjoined semiconductor die structure 904 is an active semiconductor die. Hence, in such examples, the fourth semiconductor die 906-4 may be electrically coupled with the first semiconductor die 906-1, the second semiconductor die 906-2, and the third semiconductor die 906-3. Furthermore, the conjoined semiconductor die structure 904 may be coupled to the plurality of electrical leads 916 in any suitable manner, such as any of the methods described herein. Those having ordinary skill in the art, using the disclosures provided herein, will understand that the power semiconductor device package 900 and the conjoined semiconductor die structure 904 may have any of the arrangements and/or configurations described herein and/or any variation thereof.

FIGS. 10-11 depict example semiconductor packages having conjoined semiconductor die structures with more than two semiconductor die for purposes of illustration and discussion. Those having ordinary skill in the art, using the disclosures provided herein, will understand that different semiconductor package configurations, and different conjoined semiconductor die structures having more than four semiconductor die, may be used without deviating from the scope of the present disclosure.

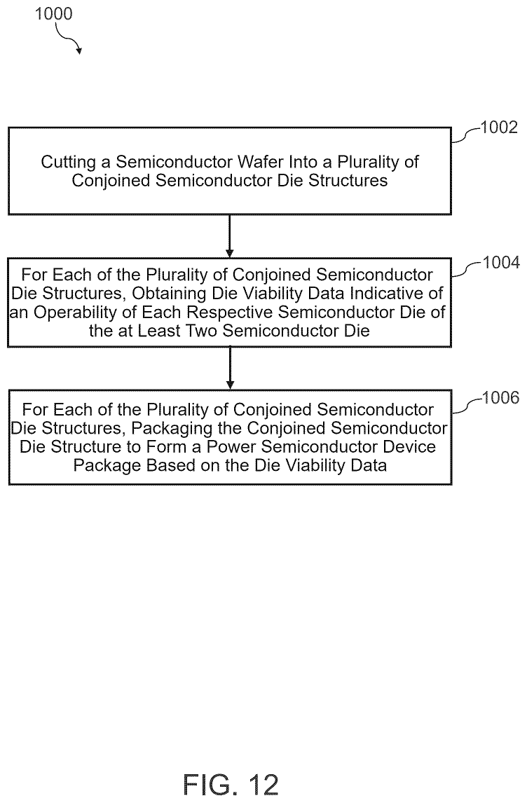

FIG. 12 depicts a flow chart diagram of an example method 1000 according to example embodiments of the present disclosure. FIG. 12 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 1002, the method 1000 includes cutting a semiconductor wafer into a plurality of conjoined semiconductor die structures. Each conjoined semiconductor die structure may include at least two semiconductor die having a common substrate (e.g., monolithic substrate on a side of each of the plurality of conjoined semiconductor die structures), such as at least three semiconductor die having a common substrate, such as four or more semiconductor die having a common substrate. In some examples, each conjoined semiconductor die structure may include at least two semiconductor die having MOSFETs. In some examples, each conjoined semiconductor die structure may include at least two semiconductor die having Schottky diodes. Those having ordinary skill in the art, using the disclosures provided herein, will understand that any suitable semiconductor die having any suitable semiconductor device may be used without deviating from the scope of the present disclosure.

At 1004, the method 1000 includes, for each of the plurality of conjoined semiconductor die structures, obtaining die viability data indicative of an operability of each respective semiconductor die of the at least two semiconductor die.

At 1006, the method 1000 includes, for each of the plurality of conjoined semiconductor die structures, packaging the conjoined semiconductor die to form a power semiconductor device package based on the die viability data. In some examples, to package each of the plurality of conjoined semiconductor die structures, the method 1000 may include providing an encapsulating material around at least a portion of the conjoined semiconductor die structure to form a housing.

For instance, in some examples, the method 1000 may include determining each of the at least two semiconductor die are active semiconductor die based on the die viability data. In such examples, each conjoined semiconductor die structure may be packaged to form a power semiconductor device package such that each of the at least two semiconductor die are electrically coupled in the power semiconductor device package.

In some examples, the method 1000 may include determining at least one semiconductor die is an inactive semiconductor die and at least one semiconductor die is an active semiconductor die based on the die viability data. In such examples, each conjoined semiconductor die structure may be packaged to form a power semiconductor device package such that no current flows through the inactive semiconductor die during operation of the power semiconductor device package.

In some examples, the method 1000 may include determining each of the at least two semiconductor die are inactive semiconductor die based on the die viability data. In such examples, in response to determining that each of the at least two semiconductor die are inactive semiconductor die, the method 1000 may include discarding the conjoined semiconductor die structure that includes the at least two inactive semiconductor die.

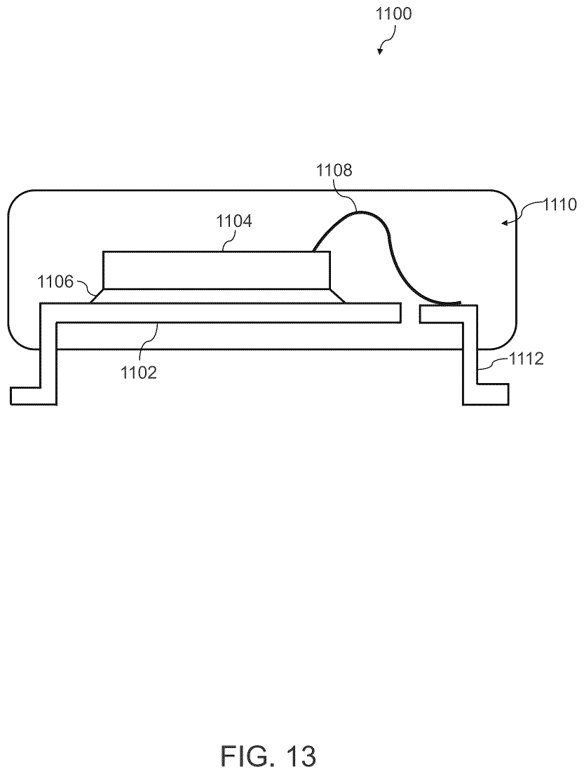

FIG. 13 depicts an example power semiconductor device package 1100 of a conjoined semiconductor die structure according to example embodiments of the present disclosure. The semiconductor package 1100 may be, for instance, a discrete power semiconductor device package. FIG. 13 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 13 is intended to represent structures for identification and description and is not intended to represent the structures to physical scale.

As shown, the power semiconductor device package 1100 may include a conductive submount 1102 (e.g., a patterned conductive substrate, lead frame, clip structure or other power substrate) on which a conjoined semiconductor die structure 1104 containing one or more power devices (e.g., transistors, diodes, etc.) is attached using a die-attach material 1106. It should be understood that the conjoined semiconductor die structure 1104 may correspond to any of the semiconductor die disclosed herein and may be fabricated using any of the methods disclosed herein.

The die-attach material 1106 may provide a thermal, mechanical, and electrical connection between the conjoined semiconductor die structure 1104 and the conductive submount 1102. In some examples, the conjoined semiconductor die structure 1104 may also be connected to the conductive submount 1102 using wire bonds 1108. An encapsulating material 1110 (e.g., epoxy mold compound (EMC)) may fill the space around the conjoined semiconductor die structure 1104 and the submount 1102, thereby forming a housing. The power semiconductor device package 1100 may further include one or more connection structures, such as electrical leads 1112, that extend outward from the housing (e.g., outward from the encapsulating material 1110).

The power semiconductor device package 1100 may include one or more metallization structures, such as any of the metallization structures disclosed herein. More particularly, the conjoined semiconductor die structure 1104 may include one or more metallization structures, such as bonding pads. The bonding pads may be coupled to the one or more electrical leads 1112 using the wire bonds 1108. The wire bonds 1108 may be aluminum and/or copper. The wire bonds 1108 may have a thickness of about 15 mil to about 20 mil (e.g., about 381 μm to about 508 μm). As noted above, the bonding pads may have a thickness, for instance, of about 4 μm or less. A backside metallization layer on the conjoined semiconductor die structure 1104 may be coupled to the submount 1102 (e.g., lead frame) using, for instance, the die-attach material 1106. The encapsulating material 1110 may encapsulate the conjoined semiconductor die structure 1104, including its metallization structures, wire bonds 1108, submount 1102, and other portions of the power semiconductor device package 1100. In some examples, the encapsulating material 1110 may directly contact the metallization structures (e.g., bonding pads, backside metallization layer, etc.) of the power semiconductor device package 1100.

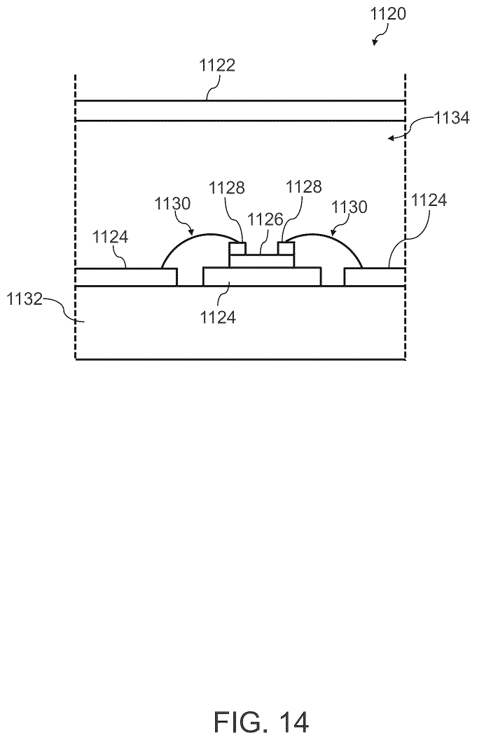

FIG. 14 depicts a cross-sectional view of an example power semiconductor device package of a semiconductor device 1120 according to example embodiments of the present disclosure. The semiconductor device 1120 of FIG. 14 is a portion of a power module. FIG. 14 is intended to represent structures for identification and description and is not intended to represent the structures to physical scale. The semiconductor device 1120 may include a housing 1122. The semiconductor device 1120 may include a conductive submount 1124 (e.g., a patterned conductive submount) on which a conjoined semiconductor die structure 1126 is mounted (e.g., using a die-attach material). It should be understood that the conjoined semiconductor die structure 1126 may correspond to any of the conjoined semiconductor die structures disclosed herein and may be fabricated using any of the methods disclosed herein. For instance, the conjoined semiconductor die structure 1126 may be mounted on submount 1124 using a die-attach material that includes a sintered material, such as sintered silver and/or sintered copper. The conjoined semiconductor die structure 1126 may include one or more metallization structures, such as bonding pads 1128. In some embodiments, the conjoined semiconductor die structure 1126 may be connected to the conductive submount 1124 using wire bonds 1130. The conductive submount 1124 may be mounted on a base layer 1132 (e.g., an insulating layer). An inert gel 1134 may fill the space between the conjoined semiconductor die structure 1126 and the housing 1122.

FIGS. 13-14 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a power semiconductor device package. The power semiconductor device package includes a housing, a submount, and a conjoined semiconductor die structure on the submount. The conjoined semiconductor die structure includes a first semiconductor die and a second semiconductor die. The first semiconductor die and the second semiconductor die include a common substrate.

In some examples, the conjoined semiconductor die structure and the common substrate include a wide bandgap semiconductor material.

In some examples, the wide bandgap semiconductor material is silicon carbide (SiC).

In some examples, the first semiconductor die and the second semiconductor die are electrically coupled in the conjoined semiconductor die structure.

In some examples, the conjoined semiconductor die structure includes one or more electrical connectors electrically coupling the first semiconductor die and the second semiconductor die.

In some examples, one of the first semiconductor die or the second semiconductor die of the conjoined semiconductor die structure is an inactive semiconductor die.

In some examples, the inactive semiconductor die is configured to provide a heat dissipation path for the conjoined semiconductor die structure.

In some examples, the conjoined semiconductor die structure includes a first side and a second side that is opposite the first side. In some examples, the first semiconductor die includes a source contact and a gate contact on the first side of the conjoined semiconductor die structure and a drain contact on the second side of the conjoined semiconductor die structure.

In some examples, the second semiconductor die includes a source contact and a gate contact on the first side of the conjoined semiconductor die structure and a drain contact on the second side of the conjoined semiconductor die structure.

In some examples, the gate contact of the first semiconductor die includes at least two gate pads on the first side, and the gate contact of the second semiconductor die includes at least two gate pads on the first side.

In some examples, the drain contact of the first semiconductor die and the drain contact of the second semiconductor die are coupled to the common substrate.

In some examples, the drain contact of the first semiconductor die and the drain contact of the second semiconductor die are directly on the common substrate.

In some examples, the source contact of the first semiconductor die is electrically coupled with the source contact of the second semiconductor die.

In some examples, the gate contact of the first semiconductor die is electrically coupled with the gate contact of the second semiconductor die.

In some examples, the conjoined semiconductor die structure includes a first side and a second side that is opposite the first side. In some examples, the first semiconductor die includes an anode contact on the first side of the conjoined semiconductor die structure; and a cathode contact on the second side of the conjoined semiconductor die structure. In some examples, the second semiconductor die includes an anode contact on the first side of the conjoined semiconductor die structure and a cathode contact on the second side of the conjoined semiconductor die structure.

In some examples, the cathode contact of the first semiconductor die and the cathode contact of the second semiconductor die are coupled to the common substrate.

In some examples, the cathode contact of the first semiconductor die and the cathode contact of the second semiconductor die are directly on the common substrate.

In some examples, the anode contact of the first semiconductor die is electrically coupled with the anode contact of the second semiconductor die.

In some examples, the conjoined semiconductor die structure includes a first side and a second side that is opposite the first side, and the conjoined semiconductor die structure further includes one or more uncut scribe lines on the first side between the first semiconductor die and the second semiconductor die.

In some examples, the one or more uncut scribe lines include a non-metal region.

In some examples, the common substrate includes a monolithic substrate on the second side.

In some examples, the conjoined semiconductor die structure includes an edge termination region extending around at least a portion of the first semiconductor die and the second semiconductor die.

In some examples, at least a portion of the edge termination region extends between the first semiconductor die and the second semiconductor die.

In some examples, the conjoined semiconductor die structure includes a first edge termination region extending around a periphery of the first semiconductor die and a second edge termination region extending around a periphery of the second semiconductor die.

In some examples, at least a portion of the first edge termination region is laterally adjacent to at least a portion of the second edge termination region in a central portion of the conjoined semiconductor die structure, the central portion corresponding to a portion of the conjoined semiconductor die structure between the first semiconductor die and the second semiconductor die.

In some examples, the housing at least partially encapsulates the conjoined semiconductor die structure and the submount.

In some examples, the power semiconductor device package further includes a plurality of electrical leads extending from the housing.

In some examples, the common substrate is coupled to a lead frame, and the lead frame is coupled to a drain lead of the plurality of electrical leads.

In some examples, a source structure of the conjoined semiconductor die structure is coupled to a source lead of the plurality of electrical leads.

In some examples, the source structure of the conjoined semiconductor die structure is one of a source contact of the first semiconductor die or a source contact of the second semiconductor die.

In some examples, a gate structure of the conjoined semiconductor die structure is coupled to a gate lead of the plurality of electrical leads.

In some examples, the gate structure of the conjoined semiconductor die structure is one of a gate contact of the first semiconductor die or a gate contact of the second semiconductor die.

In some examples, the common substrate is coupled to a lead frame, and the lead frame is coupled to a cathode lead of the plurality of electrical leads.

In some examples, an anode structure of the conjoined semiconductor die structure is coupled to an anode lead of the plurality of electrical leads.

In some examples, the anode structure of the conjoined semiconductor die structure is one of an anode contact of the first semiconductor die or an anode contact of the second semiconductor die.

In some examples, the first semiconductor die is coupled to the plurality of electrical leads via a first plurality of electrical connectors, and the second semiconductor die is coupled to the plurality of electrical leads via a second plurality of electrical connectors, the second plurality of electrical connectors being different from the first plurality of electrical connectors.

In some examples, the conjoined semiconductor die structure further includes a third semiconductor die, the third semiconductor die including the common substrate.

In some examples, the third semiconductor die is electrically coupled with the first semiconductor die and the second semiconductor die.

In some examples, the conjoined semiconductor die structure further includes a fourth semiconductor die, the fourth semiconductor die including the common substrate.

In some examples, the fourth semiconductor die is electrically coupled with the first semiconductor die, the second semiconductor die, and the third semiconductor die.

In some examples, each of the first semiconductor die and the second semiconductor die include a wide bandgap semiconductor material, the wide bandgap semiconductor material being one of silicon carbide (SiC) or a Group III-nitride.

In some examples, each of the first semiconductor die and the second semiconductor die include a metal-oxide-semiconductor field-effect transistor (MOSFET).

In some examples, each of the first semiconductor die and the second semiconductor die include a Schottky diode.

Another example aspect of the present disclosure is directed to a method. The method includes cutting a semiconductor wafer into a plurality of conjoined semiconductor die structures. Each conjoined semiconductor die structure includes at least two semiconductor die having a common substrate. The method further includes, for each of the plurality of conjoined semiconductor die structures, obtaining die viability data indicative of an operability of each respective semiconductor die of the at least two semiconductor die and packaging the conjoined semiconductor die structure to form a power semiconductor device package based on the die viability data.

In some examples, for each of the plurality of conjoined semiconductor die structures, packaging the conjoined semiconductor die structure to form the power semiconductor device package includes determining at least one semiconductor die is an inactive semiconductor die and at least one semiconductor die is an active semiconductor die based on the die viability data and packaging the conjoined semiconductor die structure to form the power semiconductor device package such that no current flows through the inactive semiconductor die during operation.

In some examples, for each of the plurality of conjoined semiconductor die structures, packaging the conjoined semiconductor die structure to form the power semiconductor device package includes determining each of the at least two semiconductor die are active semiconductor die based on the die viability data and packaging the conjoined semiconductor die structure to form the power semiconductor device package such that each of the at least two semiconductor die are electrically coupled in the power semiconductor device package.

In some examples, the method further includes, for each of the plurality of conjoined semiconductor die structures determining each of the at least two semiconductor die are inactive semiconductor die based on the die viability data and, in response to determining that each of the at least two semiconductor die are inactive semiconductor die, discarding the conjoined semiconductor die structure comprising the at least two semiconductor die.

In some examples, for each of the plurality of conjoined semiconductor die structures, packaging the conjoined semiconductor die structure to form the power semiconductor device package includes providing an encapsulating material around at least a portion of the conjoined semiconductor die structure to form a housing.

In some examples, each conjoined semiconductor die structure and each common substrate include a wide bandgap semiconductor material.

In some examples, the wide bandgap semiconductor material is silicon carbide (SiC).

In some examples, each conjoined semiconductor die structure of the plurality of conjoined semiconductor die structures includes a first semiconductor die and a second semiconductor die.

In some examples, each of the first semiconductor die and the second semiconductor die include a metal-oxide-semiconductor field-effect transistor (MOSFET).

In some examples, the first semiconductor die includes a drain contact and the second semiconductor die includes a drain contact, and the drain contact of the first semiconductor die and the drain contact of the second semiconductor die are coupled to the common substrate.

In some examples, the drain contact of the first semiconductor die and the drain contact of the second semiconductor die are directly on the common substrate.

In some examples, each of the first semiconductor die and the second semiconductor die include a Schottky diode.

In some examples, the first semiconductor die includes a cathode contact and the second semiconductor die includes a cathode contact, and the cathode contact of the first semiconductor die and the cathode contact of the second semiconductor die are coupled to the common substrate.

In some examples, the cathode contact of the first semiconductor die and the cathode contact of the second semiconductor die are directly on the common substrate.

In some examples, each conjoined semiconductor die structure further includes at least one uncut scribe line between the first semiconductor die and the second semiconductor die.

In some examples, the at least one uncut scribe line includes at least one non-metal region.

In some examples, each conjoined semiconductor die structure includes an edge termination region extending around at least a portion of the first semiconductor die and the second semiconductor die.

In some examples, at least a portion of the edge termination region extends between the first semiconductor die and the second semiconductor die.

In some examples, the first semiconductor die and the second semiconductor die include a wide bandgap semiconductor material, the wide bandgap semiconductor material being one of silicon carbide (SiC) or a Group III-nitride.

In some examples, for each conjoined semiconductor die structure, the common substrate includes a monolithic substrate on a side of the conjoined semiconductor die structure.

In some examples, each conjoined semiconductor die structure includes at least three semiconductor die, each of the at least three semiconductor die having the common substrate.

In some examples, each conjoined semiconductor die structure includes four or more semiconductor die, each of the four or more semiconductor die having the common substrate.

Another example aspect of the present disclosure is directed to a power semiconductor device package. The power semiconductor device package includes a housing, a submount, and a conjoined semiconductor die on the submount. The conjoined semiconductor die includes a first semiconductor die unit, a second semiconductor die unit, and one or more uncut scribe lines on a side of the conjoined semiconductor die. The one or more uncut scribe lines are between the first semiconductor die unit and the second semiconductor die unit.

In some examples, the one or more uncut scribe lines are on a first side of the conjoined semiconductor die, and the conjoined semiconductor die further includes a common substrate on a second side of the conjoined semiconductor die that is opposite the first side.

In some examples, the conjoined semiconductor die and the common substrate include a wide bandgap semiconductor material.

In some examples, the wide bandgap semiconductor material is silicon carbide (SiC).

In some examples, the common substrate is coupled to a drain contact of the first semiconductor die unit and to a drain contact of the second semiconductor die unit.

In some examples, the common substrate is coupled to a cathode contact of the first semiconductor die unit and to a cathode contact of the second semiconductor die unit.

In some examples, the common substrate includes a monolithic substrate on the second side.

In some examples, the first semiconductor die unit includes a source contact and a gate contact on the first side of the conjoined semiconductor die and a drain contact on the second side of the conjoined semiconductor die. In some examples, the second semiconductor die unit includes a source contact and a gate contact on the first side of the conjoined semiconductor die and a drain contact on the second side of the conjoined semiconductor die.

In some examples, the source contact of the first semiconductor die unit is electrically coupled with the source contact of the second semiconductor die unit.

In some examples, the gate contact of the first semiconductor die unit is electrically coupled with the gate contact of the second semiconductor die unit.

In some examples, the first semiconductor die unit includes an anode contact on the first side of the conjoined semiconductor die and a cathode contact on the second side of the conjoined semiconductor die. In some examples, the second semiconductor die unit includes an anode contact on the first side of the conjoined semiconductor die and a cathode contact on the second side of the conjoined semiconductor die.

In some examples, the anode contact of the first semiconductor die unit is electrically coupled with the anode contact of the second semiconductor die unit.

In some examples, the power semiconductor device package further includes a plurality of electrical leads extending from the housing.

In some examples, the common substrate is coupled to a lead frame, and the lead frame is coupled to a drain lead of the plurality of electrical leads.

In some examples, a source structure of the conjoined semiconductor die is coupled to a source lead of the plurality of electrical leads, the source structure being one of a source contact of the first semiconductor die unit or a source contact of the second semiconductor die unit.

In some examples, a gate structure of the conjoined semiconductor die is coupled to a gate lead of the plurality of electrical leads, the gate structure being one of a gate contact of the first semiconductor die unit or a gate contact of the second semiconductor die unit.

In some examples, the common substrate is coupled to a lead frame, and the lead frame is coupled to a cathode lead of the plurality of electrical leads.

In some examples, an anode structure of the conjoined semiconductor die is coupled to an anode lead of the plurality of electrical leads, the anode structure being one of an anode contact of the first semiconductor die unit or an anode contact of the second semiconductor die unit.

In some examples, the first semiconductor die unit is coupled to the plurality of electrical leads via a first plurality of electrical connectors, and the second semiconductor die unit is coupled to the plurality of electrical leads via a second plurality of electrical connectors, the second plurality of electrical connectors being different from the first plurality of electrical connectors.

In some examples, the first semiconductor die unit and the second semiconductor die unit are electrically coupled.

In some examples, the conjoined semiconductor die includes one or more electrical connectors electrically coupling the first semiconductor die unit and the second semiconductor die unit.

In some examples, one of the first semiconductor die unit or the second semiconductor die unit of the conjoined semiconductor die is an inactive semiconductor die unit.

In some examples, the one or more uncut scribe lines include a non-metal region.

In some examples, the conjoined semiconductor die includes an edge termination region extending around at least a portion of the first semiconductor die unit and the second semiconductor die unit.

In some examples, at least a portion of the edge termination region extends between the first semiconductor die unit and the second semiconductor die unit.

In some examples, the conjoined semiconductor die includes a first edge termination region extending around a periphery of the first semiconductor die unit and a second edge termination region extending around a periphery of the second semiconductor die unit.

In some examples, at least a portion of the first edge termination region is laterally adjacent to at least a portion of the second edge termination region in a central portion of the conjoined semiconductor die, the central portion corresponding to a portion of the conjoined semiconductor die between the first semiconductor die unit and the second semiconductor die unit.

In some examples, the housing at least partially encapsulates the conjoined semiconductor die and the submount.

In some examples, the conjoined semiconductor die further includes a third semiconductor die unit and one or more uncut scribe lines on the side of the conjoined semiconductor die between the third semiconductor die unit and one of the first semiconductor die unit or the second semiconductor die unit.

In some examples, the third semiconductor die unit is electrically coupled with the first semiconductor die unit and the second semiconductor die unit.

In some examples, each of the first semiconductor die and the second semiconductor die include a wide bandgap semiconductor material, the wide bandgap semiconductor material being one of silicon carbide (SiC) or a Group III-nitride.

In some examples, each of the first semiconductor die unit and the second semiconductor die unit include one of a metal-oxide-semiconductor field-effect transistor (MOSFET) or a Schottky diode.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device package, comprising:
a housing;
a submount; and
a conjoined semiconductor die structure on the submount, the conjoined semiconductor die structure comprising a first semiconductor die and a second semiconductor die, the first semiconductor die and the second semiconductor die comprising a common substrate.

2. The power semiconductor device package of claim 1, wherein the conjoined semiconductor die structure and the common substrate comprise a wide bandgap semiconductor material.

3. The power semiconductor device package of claim 2, wherein the wide bandgap semiconductor material is silicon carbide (SiC).

4. The power semiconductor device package of claim 1, wherein the first semiconductor die and the second semiconductor die are electrically coupled in the conjoined semiconductor die structure.

5. The power semiconductor device package of claim 1, wherein one of the first semiconductor die or the second semiconductor die of the conjoined semiconductor die structure is an inactive semiconductor die.

6. The power semiconductor device package of claim 5, wherein the inactive semiconductor die is configured to provide a heat dissipation path for the conjoined semiconductor die structure.

7. The power semiconductor device package of claim 1, wherein the conjoined semiconductor die structure comprises a first side and a second side that is opposite the first side, and wherein:
the first semiconductor die comprises:
a source contact and a gate contact on the first side of the conjoined semiconductor die structure; and
a drain contact on the second side of the conjoined semiconductor die structure; and
the second semiconductor die comprises:
a source contact and a gate contact on the first side of the conjoined semiconductor die structure; and
a drain contact on the second side of the conjoined semiconductor die structure.

8. The power semiconductor device package of claim 7, wherein the drain contact of the first semiconductor die and the drain contact of the second semiconductor die are coupled to the common substrate.

9. The power semiconductor device package of claim 7, wherein the source contact of the first semiconductor die is electrically coupled with the source contact of the second semiconductor die.

10. The power semiconductor device package of claim 7, wherein the gate contact of the first semiconductor die is electrically coupled with the gate contact of the second semiconductor die.

11. The power semiconductor device package of claim 1, wherein the conjoined semiconductor die structure comprises a first side and a second side that is opposite the first side, and wherein:
the first semiconductor die comprises:
an anode contact on the first side of the conjoined semiconductor die structure; and
a cathode contact on the second side of the conjoined semiconductor die structure; and
the second semiconductor die comprises:
an anode contact on the first side of the conjoined semiconductor die structure; and
a cathode contact on the second side of the conjoined semiconductor die structure.

12. The power semiconductor device package of claim 11, wherein the cathode contact of the first semiconductor die and the cathode contact of the second semiconductor die are coupled to the common substrate.

13. The power semiconductor device package of claim 11, wherein the anode contact of the first semiconductor die is electrically coupled with the anode contact of the second semiconductor die.

14. The power semiconductor device package of claim 1, wherein the conjoined semiconductor die structure comprises a first side and a second side that is opposite the first side, the conjoined semiconductor die structure further comprising one or more uncut scribe lines on the first side between the first semiconductor die and the second semiconductor die.

15. The power semiconductor device package of claim 14, wherein the common substrate comprises a monolithic substrate on the second side.

16. The power semiconductor device package of claim 1, wherein the conjoined semiconductor die structure comprises an edge termination region extending around at least a portion of the first semiconductor die and the second semiconductor die.

17. The power semiconductor device package of claim 1, wherein the conjoined semiconductor die structure comprises:
a first edge termination region extending around a periphery of the first semiconductor die; and
a second edge termination region extending around a periphery of the second semiconductor die.

18. The power semiconductor device package of claim 1, wherein each of the first semiconductor die and the second semiconductor die comprise a wide bandgap semiconductor material, the wide bandgap semiconductor material being one of silicon carbide (SiC) or a Group III-nitride.

19. A method, comprising:
cutting a semiconductor wafer into a plurality of conjoined semiconductor die structures, each conjoined semiconductor die structure comprising at least two semiconductor die having a common substrate; and
for each of the plurality of conjoined semiconductor die structures:
obtaining die viability data indicative of an operability of each respective semiconductor die of the at least two semiconductor die; and
packaging the conjoined semiconductor die structure to form a power semiconductor device package based on the die viability data.

20. A power semiconductor device package, comprising:
a housing;
a submount; and
a conjoined semiconductor die on the submount, the conjoined semiconductor die comprising:
a first semiconductor die unit;
a second semiconductor die unit; and
one or more uncut scribe lines on a side of the conjoined semiconductor die, the one or more uncut scribe lines between the first semiconductor die unit and the second semiconductor die unit.
